(19) United States
(12) Patent Application Publication
(10) Pub. No.: US 2011/0083742 A1
(43) Pub. Date: Apr. 14, 2011

(54) MULTICONVERTER SYSTEM COMPRISING SPECTRAL SEPARATING REFLECTOR ASSEMBLY AND METHODS THEREOF

(75) Inventor: James F. Munro, Walworth, NY (US)

(73) Assignee: RNY Solar, Walworth, NY (US)

(21) Appl. No.: 12/880,976

(22) Filed: Sep. 13, 2010

Related U.S. Application Data
(60) Provisional application No. 61/277,896, filed on Oct. 1, 2009.

(51) Int. Cl. H01L 31/0232

(52) U.S. Cl. 136/259

(57) ABSTRACT

A system is set forth herein which can include a plurality of reflectors adapted to reflect light. The system can further include a plurality of photovoltaic cells. A certain reflector of the plurality of reflectors adapted to reflect light can be adapted to reflect light within a certain wavelength band and can be further adapted to transmit light outside of the certain wavelength band. A photovoltaic cell can be disposed to receive light reflected by the certain reflector.

### CROSS REFERENCE TO RELATED APPLICATIONS

This application claims priority under 35 U.S.C. §119(e) to U.S. Provisional Patent Application No. 61/277,896, entitled “Concentrated Spectrally Separated Multiconverter System And Methods Thereof” filed Oct. 1, 2009. This application is also related to U.S. patent application Ser. No. 12/880,954 (Attorney Docket No. 1620-007) entitled “Multiconverter System Comprising Spectral Separating Reflector Assembly And Methods Thereof” filed on the date of filing of the present application. Each of the above applications; namely, U.S. Provisional Patent Application No. 61/277,896 and U.S. patent application Ser. No. 12/880,954 (Attorney Docket No. 1620-007) is incorporated herein by reference.

### FIELD OF THE INVENTION

This invention generally relates to photovoltaic converters and, more particularly, to spectral-splitting concentrated solar photovoltaic converters.

### BACKGROUND OF THE INVENTION

Optical concentrators are widely used in solar photovoltaic converters for two important reasons. First they allow for reduced system cost since less photovoltaic conversion material—which is by far the most expensive component in a PV system—is required. Typically CPV systems can have a PV-cell that has less than 0.2% of the area of a PV-cell used in a non-concentrated PV conversion system. Furthermore it is well known that PV-cells illuminated by higher flux densities achieve higher solar-to-electricity conversion efficiencies.

A typical prior-art CPV system, illustrated in FIG. 1, consists of a condensing fresnel lens 2 and a PV-cell 6 located at the focal point 5 of the condensing fresnel lens 2. Both the condensing fresnel lens 2 and the PV-cell 6 share a common optical axis 3. In operation solar radiation 1 is incident on the condensing fresnel lens 2 which causes the solar radiation 1 to be condensed and brought to a focus at a focal point 5 on the PV-cell 6.

A fresnel optical element 2, as described and referenced herein, can be of two types: one that operates in transmission and is called a fresnel lens and one that operates in reflection which is called a fresnel mirror or fresnel reflector. Both fresnel lenses and fresnel reflectors are commonly employed in solar concentrators, and are also utilized in the present invention. Both such devices are comprised of a fresnel microstructure that consists of a series of rather shallow grooves that are generally sawtooth in cross-section. The longer surface of the groove that performs the optical work is called the slope surface, and the other surface that connects the slope surfaces together is called the draft or riser surfaces. The angle of the slope surfaces generally change slightly from groove to groove, being more shallow near the optical axis of the fresnel, and steeper at the edges. At the same time the depth of the drafts are smaller near the optical axis of the fresnel microstructure and greater at the edge.

There are two major problems with the typical prior-art CPV system. Firstly, because of chromatic aberration, the focal point 5 is not a point, but can be several centimeters in diameter depending on the geometry of the optical configuration and the range of wavelengths passed by the fresnel lens 2. As will be discussed later, the ideal condensing fresnel lens 2 will transmit and bring to a focus all optical energy within the wavelengths of the sun that contain significant amounts of energy, this range of wavelengths typically being from 350 nm to 1800 nm. The dispersive nature of the material comprising the condensing fresnel lens 2 causes the refractive index of the material to vary significantly over this wavelength range, which in turn causes the optical power of the condensing fresnel lens 2 to vary as a function of wavelength, which in turn causes the diameter of the focal spot 5 (given a constant back focal distance) to also vary with wavelength. To compensate for this, additional condensing optics can be installed atop the PV-cell 6, or the PV-cell 6 can be made substantially larger to ensure that it captures all of the energy of the worst-case focal spot. Both of these solutions, however, drive up system cost and complexity, and reduce efficiency.

A second problem with the typical prior-art CPV system is that only one solar cell 6 is used for each condensing fresnel lens 2. As will be discussed later, it is well known that utilizing several PV-cells having a variety of PV junction bandgaps can significantly improve PV conversion efficiency. Indeed, some companies have begun offering so-called tandem PV-cells in which two or three PV-cells are grown atop one another in a semiconductor foundry. In a typical triple junction (“3J”) cell, the uppermost junction typically converts the shortest wavelengths to electricity, the middle junction converts a middle band of solar wavelengths to electricity, and the lowest junction converts the longest wavelengths to electricity. Such a configuration does offer a significant improvement in conversion efficiency, as efficiencies on the order or 40% have been reported. However, there are a large number of layers between junctions within a tandem cell, and the addition of each layer dramatically increases device complexity, decreases fabrication yield, and drives up the device cost.

Accordingly, an improved solar concentrator would be one that is configured to use several low-cost single-junction solar cells having different bandgaps, and at the same time does not suffer from the large focal spot sizes resulting from chromatic dispersion effects of the optical condenser. One such prior art spectral-separating CPV system is illustrated in FIG. 2. In this configuration sunlight 1, is incident on a condensing fresnel lens 2 which causes the sunlight to converge along an optical axis 3. The converging sunlight 4 is then incident on a reflector 11 that is treated with a reflective layer 10 that is reflective to one spectral band of wavelengths and transmissive to all others. The still-converging light 14 reflected by reflective layer 10 is brought to a focus on a PV-cell 15 whose response function is ideally suited for converting the wavelengths of light within converging light 14 into electricity.

Converging light 16 that is transmitted through reflector 11 contains all solar wavelengths not reflected by reflective layer 10 and not otherwise absorbed. The converging light 16 is then incident on a reflector 13 that is treated with a reflective layer 12 that is reflective to a second spectral band of wavelengths (different than the reflected spectral band of reflective layer 10) and transmissive to all others. The still-converging light 17 reflected by the reflective layer 12 is brought to a focus on a PV-cell 18 whose response function is ideally suited for converting the wavelengths of light within converging light 17 into electricity.

Converging light 19 that is transmitted through reflective layer 12 contains all solar wavelengths not otherwise reflected by reflective layers 10 and 12 and not otherwise absorbed. The converging light 19 then comes to a focus on a PV-cell 20 whose response function is ideally suited for converting the wavelengths of light within converging light 19 into electricity. In this way the solar irradiance incident on the fresnel lens is spectrally separated into three spectral bands, and each spectral band is concentrated and directed onto a PV-cell whose spectral response function is well-matched to the spectrum of sunlight that is incident upon it so that the solar irradiance can be converted to electricity with high efficiency.

While the prior art spectral-splitting and conversion configuration of FIG. 2 does offer a tremendous improvement in efficiency over the FIG. 1 embodiment, it does have its deficiencies and limitations. For example, the first reflector 11 is physically large and therefore expensive. Secondly, it is difficult to add more reflectors and separate the sunlight into more than the three spectral bands described above due to spacing constraints, although dividing the solar spectrum into more than three bands is beneficial. Finally, fresnel reflection of light on the non-reflector sides of reflectors 11 and 13 greatly diminishes the amount of light that reaches lower PV-cells 18 and 20, and therefore overall system efficiency is reduced. Accordingly, a concentrated solar converter that utilizes a spectral splitter whose reflectors are all small and inexpensive, can be scaled such that four or more spectral bands are generated, and does not suffer from fresnel losses, would be a substantial improvement over the prior art.

### SUMMARY OF THE INVENTION

A system is set forth herein which can include a plurality of reflectors adapted to reflect light. The system can further include a plurality of photovoltaic cells. A certain reflector of the plurality of reflectors adapted to reflect light can be adapted to reflect light within a certain wavelength band and can be further adapted to transmit light outside of the certain wavelength band. A photovoltaic cell can be disposed to receive light reflected by the certain reflector.

### BRIEF DESCRIPTION OF THE DRAWINGS

FIG. 1 is a side-view of a prior art concentrating photovoltaic (CPV) converter;

FIG. 2 is a side-view of a prior art high-efficiency CPV converter;

FIG. 3 is a side-view of a high-efficiency CPV converter in accordance with one embodiment of the present invention;

FIG. 4 is a magnified side-view of the reflector assembly of a high-efficiency CPV converter in accordance with one embodiment of the present invention;

FIG. 5 is a magnified side-view of the reflector assembly in which only two reflectors are shown, with geometric annotations, for the optical analysis of the reflector assembly;

FIG. 6 is a magnified side-view of the reflector assembly in which only two reflectors are shown, with geometric annotations, for the optical analysis of the reflector assembly in which one or more of the lower reflective surfaces are microstructured with fresnel grooves;

FIG. 7 is a side-view TracePro raytrace output of a four-cell PV concentrator in accordance with one embodiment of the present invention;

FIG. 8 is a magnified side-view TracePro raytrace output of a four-reflector reflector assembly in accordance with one embodiment of the present invention;

FIG. 9 is an isometric view of a TracePro raytrace output of a four-cell concentrator in accordance with one embodiment of the present invention;

FIG. 10 is a side-view TracePro raytrace output of a six-cell PV concentrator in accordance with one embodiment of the present invention;

FIG. 11 is a magnified oblique-view TracePro raytrace output of a six-reflector reflector assembly in accordance with one embodiment of the present invention;

FIG. 12 is an alternate magnified side-view TracePro raytrace output of a six-reflector reflector assembly in accordance with one embodiment of the present invention in which the compound angle of the reflectors is illustrated;

FIG. 13 is an oblique-view of a TracePro raytrace output of a six-cell concentrator in accordance with one embodiment of the present invention;

FIG. 14 is a side-view of an alternate five-cell PV concentrator in accordance with one embodiment of the present invention in which the reflector assembly is not located on the optical axis of the concentrating lens;

FIG. 15 is a side-view of an alternate five-cell PV concentrator in accordance with one embodiment of the present invention in which the reflector assembly contains only four reflectors;

FIG. 16 is a side-view of a five-cell PV concentrator in accordance with an alternate embodiment of the present invention in which one or more of the reflective surfaces of the reflector assembly have optical power and the PV-cells are coplanar;

FIG. 17 is a magnified side-view of a reflector assembly of a five-cell PV concentrator in accordance with an alternate embodiment of the present invention illustrating the fresnel microstructure of the lower four reflective surfaces;

FIG. 18 is a plan-view of one microstructured reflective surface of the reflector assembly illustrated in FIG. 17;

FIG. 19 is a side-view of one microstructured reflective surface of the reflector assembly in which the microstructure is elastic and a rigid supporting layer is installed between the microstructure and the reflector layer;

FIG. 20A is a graph of solar spectral insulation in which the spectrum is divided into four spectral bands having substantially unequal power;

FIG. 20B is a graph of solar spectral insulation in which the spectrum is divided into four spectral bands having substantially equal power;

FIG. 21 is a graph of the refractive index of silicone as a function of wavelength;

FIG. 22 is a graph of the refractive index of acrylic as a function of wavelength;

FIG. 23A is a graph of fresnel reflectance as a function of incidence angle seen at an acrylic-air interface when the light ray originates on the acrylic side of the interface;

FIG. 23B is a graph of fresnel reflectance as a function of incidence angle seen at a silicone-acrylic interface when the light ray originates on the silicone side of the interface;

FIG. 23C is a graph of fresnel reflectance as a function of incidence angle seen at an acrylic-air interface when the light ray originates on the air side of the interface;

FIG. 24 is a graph of fresnel reflectance as a function of refractive index of one medium of the interface, when the other medium of the interface is air or silicone;

FIG. 25 is a graph illustrating the efficiency of the reflector assembly as a function of the number of spectral bands, with air between the mirror substrates of the reflector assembly or with silicone between the mirror substrates of the reflector assembly;

FIG. 26A is a graph illustrating PV-cell responsivity for four common PV-cells as a function of wavelength overlaid with a graph of solar insulation;

FIG. 26B is a graph illustrating PV-cell responsivity for three common PV-cells as a function of wavelength overlaid with a graph of solar insulation;

FIG. 27 is a side-view of a three-band converter having a highly efficient reflector assembly having a curved lower reflector, and three PV-cells with secondary optics in which one of the cells off to the side is larger than the others;

FIG. 28 is a magnified side-view of the highly efficient reflector assembly with a reflector defining a curved lower surface, three PV-cells with secondary optics in which one of the cells off to the side is larger than the others;

FIG. 29 is a plot of the irradiance of the concentrated illumination incident on the larger PV-cell that occurs when the lower reflector is planar;

FIG. 30 is a plot of the irradiance of the concentrated illumination incident on the larger PV-cell that occurs when the lower reflector is curved in one dimension in accordance with a prescription that provides good uniformity of the irradiance on the larger PV-cell;

FIG. 31 is a plot of the irradiance of the concentrated illumination incident on the larger PV-cell that occurs when the lower reflector is curved in two dimensions in accordance with a prescription that provides good uniformity of the irradiance on the larger PV-cell;

FIG. 32A is a plan view of the lower reflector illustrating its size and two sections;

FIG. 32B is a graph of the sag of the lower reflector along section X-X of FIG. 32A in which the lower reflector is curved in two dimensions in accordance with a prescription that provides good uniformity of the irradiance on the larger PV-cell;

FIG. 32C is a graph of the sag of the lower reflector along section Y-Y of FIG. 32A in which the lower reflector is curved in two dimensions in accordance with a prescription that provides good uniformity of the irradiance on the larger PV-cell;

FIG. 33 is a plot of the irradiance of the concentrated illumination incident on the lower PV-cell that occurs when the lower reflector is curved in two dimensions in accordance with a prescription that provides good uniformity of the irradiance on the larger PV-cell located at the side of the reflector assembly;

FIG. 34A is a side view of one embodiment of the lower reflector having a curved reflective surface and integral mounting features;

FIG. 34B is a plan view of one embodiment of the lower reflector having a curved reflective surface and integral mounting features;

FIG. 34C is a side view of one embodiment of the lower reflector having a curved reflective surface and integral mounting features featuring an adhesive and upper reflector during the assembly process;

FIG. 34D is a side view of one embodiment of the lower reflector having a curved reflective surface and integral mounting features featuring an adhesive and upper reflector after the assembly process;

FIG. 34E is a side view of one embodiment of the lower reflector having a curved reflective surface and integral mounting features after it has been attached to the upper reflector with an adhesive and installed into a highly efficient converter;

FIG. 35 is a side view of an embodiment of a three-band converter in which the curved lower reflector is placed on a single piece substrate having a planar upper reflector and installed into the converter;

FIG. 36 is a side view of an embodiment of a four-band converter in which the upper two reflective surfaces are located on a single upper substrate, the lower curved reflective surface and optional curved lower refractive surfaces are located on a single lower substrate with an index matching adhesive placed between the upper and lower substrates;

FIG. 37 is a side view of an embodiment of a three-band converter in which the curved lower reflector is placed on a unitary substrate having a curved upper reflector and installed into the converter; and

FIG. 38 is a wiring diagram of an array of three-band converters illustrating the electrical connections between the PV-cells and an inverter.

### DETAILED DESCRIPTION OF THE INVENTION

An ideal solar concentrator is one that a) has a high concentration ratio, b) is lossless over the range of wavelengths emitted by the sun that have significant energy content, and c) directs the concentrated solar energy to a conversion cell (or cells). If multiple conversion cells are employed, wherein each cell has a different bandgap, the ideal concentrator will route to a cell only those wavelengths that the cell is most responsive to.

It is well-known to those skilled in the art that PV conversion efficiency increases with solar concentration. This is due to the fact that, while a PV-cell's output electrical current, I, increases linearly with incident solar flux, a cell's output voltage, V, increases logarithmically with current (and incident solar flux) in accordance with a semiconductor diode's V-I curve. Therefore the cell's output power, P, defined as P=I×V increases logarithmically with incident solar flux. However, this effect is reduced somewhat by increases in I²R losses in the cell, and increased temperatures resulting from a greater thermal load which increases carrier recombination within the cell. An optimal concentration ratio for a PV-cell often lies between 150 and 1500. It is interesting to note that the maximum achievable concentration ratio, which is limited by the etendue of the sun, is approximately 46,000 in air. Furthermore, most economically feasible concentrators are capable of achieving less than 25% of this value.

As mentioned earlier, the ideal concentrator is one that separates the solar energy into discrete wavelength groupings, and directs each group of concentrated solar energy onto the PV-cells that is optimal for the wavelengths that are directed to it. This can be quite a challenge, as the solar spectrum carries considerable energy from wavelengths less than 350 nm to wavelengths exceeding 1800 nm. By way of example only, a system for separating the solar energy into a plurality of wavelength bands is disclosed in U.S. Provisional Patent having Ser. No. 61/165,129 which is herein incorporated by reference in its entirety.

Not only must the ideal concentrator separate the incident solar radiation into separate wavelength bands, but it should separate the solar radiation into several bands. For example, a ten junction system (i.e., ten wavelength bands) can theoretically achieve 70% conversion efficiency at a 500× concentration ratio, whereas a four junction concentrator system can at best achieve only 60% efficiency. Clearly the more PV-cells of differing bandgap that can be cost-effectively included in a solar converter the better.

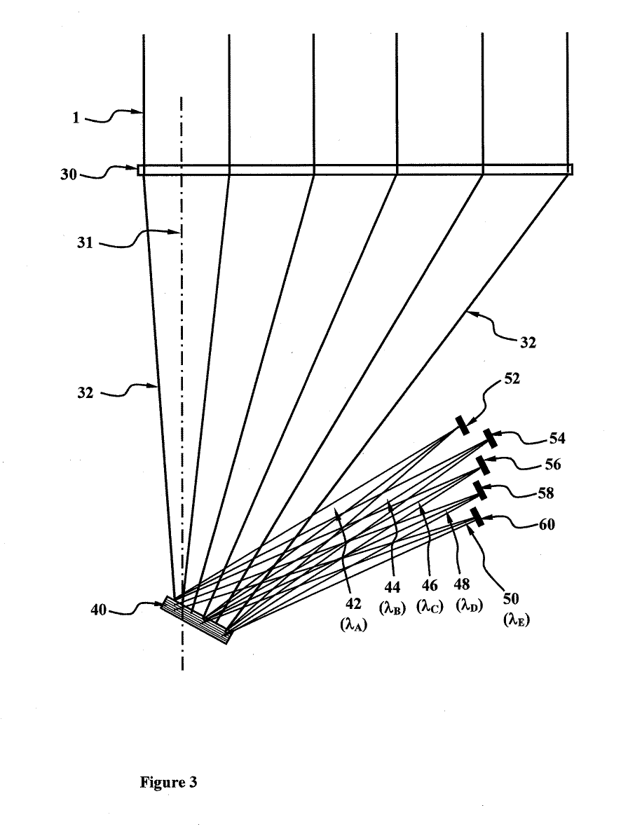

One solar concentrator embodiment of the present invention that meets the requirements for a high-efficiency solar concentrator set forth earlier is illustrated in FIG. 3. This particular embodiment is a five spectral band five-PV-cell concentrator. The conversion system in FIG. 3 consists of a condensing fresnel lens 30 having an optical axis 31, a reflector assembly 40, and five PV-cells 52, 54, 56, 58, and 60. The condensing fresnel lens 30 is a positive lens having a focal length between 25 mm and 1 meter, and an F/# between 0.5 and 5.0. Being a fresnel, it consists of a series of concentric sawtooth-shaped grooves centered about the optical axis 31. The spacing of the grooves can be constant from groove to groove, or it can vary. Either way, the spacing of the grooves can be between 0.02 mm and 10 mm. The fresnel lens 30 can be molded as a single monolithic element from a polymeric material, such as acrylic or polycarbonate, with a compression molding, injection molding, or injection-compression molding process. Alternately the fresnel lens 30 can be formed from a substrate having planar front and rear faces onto which the fresnel microstructure is molded or cast. For example, the substrate can be a film of PET onto which is cast a UV-curable resin into which the fresnel microstructure has been formed. Alternately the fresnel lens 30 can be formed from a glass substrate having planar front and rear surfaces onto which silicone fresnel microstructure has been formed. This embodiment is particularly attractive because it is well known that silicone and glass do not significantly degrade with long-term exposure to ultraviolet light contained within the solar spectrum. The fresnel microstructure can be located on the side of the lens 30 facing the sun, but preferably the fresnel microstructure would be facing the reflector assembly so that it can be protected from airborne dirt and other contaminants that can become lodged into the fresnel grooves and thereby reduce the amount of sunlight passing through the fresnel lens 30. Alternately, fresnel lens 30 can be a non-fresnel lens such as a glass or plastic lens having a plano-convex, bi-convex, or meniscus shape. Alternately fresnel lens 30 can be a diffractive optical element which can aid the spectral splitting operation of the reflector assembly 40. The planar surface of the fresnel lens 30 may be treated with an A/R (antireflective) coating or subwavelength microstructure to reduce unwanted fresnel reflection and thereby improve light transmittance through the surface. The subwavelength microstructure has the additional benefit of having self-cleaning properties owing to the so-called Lotus Effect.

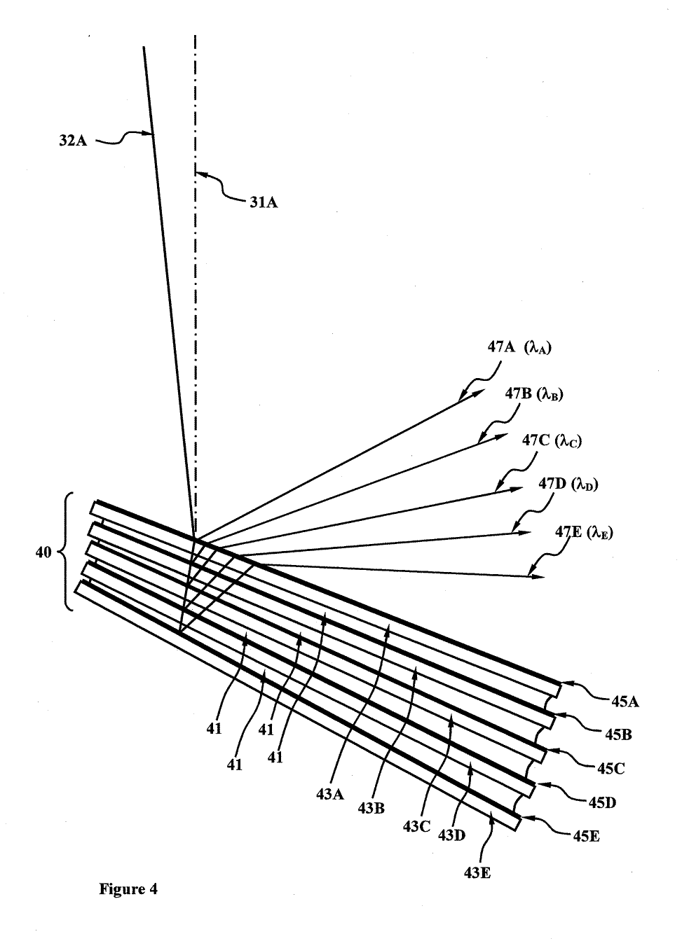

The reflector assembly 40 consists of a series of mirror-coated substrates bonded together into a sandwich configuration. As shown in the expanded view of FIG. 4, the reflector assembly 40 is made from five substrates 43A, 43B, 43C, 43D, and 43E, onto which is coated five distinct reflective coatings, 45A, 45B, 45C, 45D, and 45E, respectively after which the five coated substrates are bonded together with an adhesive or adhesive-encapsulate 41. The substrates 43A, 43B, 43C, 43D, and 43E can all be substantially the same, and made from glass or a polymer material such as acrylic or polycarbonate. The front and rear faces can be planar, or they can have optical power, produced for example, by a fresnel structure installed onto or molded into a surface. Alternately the substrates can be non-planar and having optical power produced, for example, by having a continuous curved surface as one or both of the substrate's faces. Alternately the substrate surfaces can have diffractive features, such as a grating, a holographically formed optical element, or other subwavelength microstructure to control the direction of the reflected light. The size or area of the reflectors 43A, 43B, 43C, 43D, and 43E should be kept small, such as less than nine square-inches, to keep the material and coating costs to a minimum.

The reflective coatings 45A, 45B, 45C, 45D, and 45E are installed on a surface of the substrates 43, preferably the surface facing the condensing fresnel lens 30, but can alternately be installed on the rear surface instead. The upper reflecting layers 45A, 45B, 45C, and 45D can be dielectric interference thin film stacks. The lowermost reflecting layer 45E can be a broadband reflector made from a metal such as aluminum, silver, or gold, and need not transmit any wavelengths as there are no optical components or PV-cells after this reflector to manage or utilize any transmitted light. Alternately the lowermost reflective layer 45E can also be a dielectric interference thin film stack. The uppermost reflecting layers 45A through 45D are designed such that each reflects, with high reflectivity, only a certain band of wavelengths, and transmit, with high transmittance, those wavelengths that are to be reflected by downstream reflectors. For example, the upper reflecting layer 45A could be designed to reflect light in the spectral band of 350 nm to 500 nm (corresponding to the high response portion of an InGaN PV-cell response function), and transmit with high efficiency light from 500 nm to 1800 nm; the second reflecting layer 45B would be designed to reflect light in the spectral band of 500 nm to 660 nm (corresponding to the high response portion of an InGaP PV-cell response function), and transmit with high efficiency light from 660 nm to 1800 nm; the third reflecting layer 45C could be designed to reflect light in the spectral band of 660 nm to 900 nm (corresponding to the high response portion of a GaAs PV-cell response function), and transmit with high efficiency light from 900 nm to 1800 nm; the fourth reflecting layer 45D could be designed to reflect light in the spectral band of 900 nm to 1110 nm (corresponding to the high response portion of a silicon PV-cell response function), and transmit with high efficiency light from 1110 nm to 1800 nm; and the fifth reflecting layer 45E could be designed to reflect light in the spectral band of 1110 nm to 1800 nm (corresponding to the high response portion of a Germanium PV-cell response function), although as mentioned earlier it can be a broadband reflector and reflect wavelengths outside the 1110 nm to 1800 nm spectral band as well. These spectral bands as described in this paragraph are only one example of the spectral splits available for a five band spectral separating reflector assembly 40, as a large number of permutations are available and can be readily adjusted to suit the response function of a variety of PV-cells. Likewise, instead of there being five reflectors in the reflector assembly 40, any number between two and ten reflectors can be provided, or even up to 20.

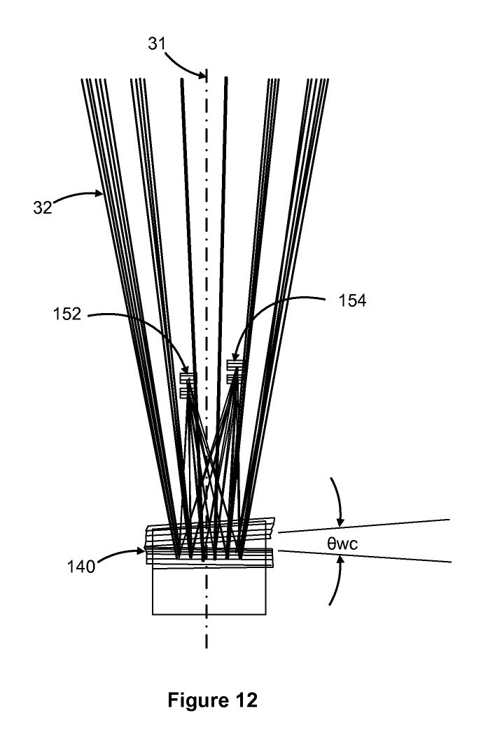

The reflectors 43A, 43B, 43C, 43D, and 43E within the reflector assembly 40 are bonded together with an adhesive 41 that is substantially transparent to all wavelengths that PV-cells 54, 56, 58, and 60 are responsive to. Note that PV-cell 52 was excluded from this list because light that is incident upon it does not pass through the adhesive material 41. An ideal candidate for the adhesive is silicone as it does not degrade with many years of exposure to solar irradiation. The average thickness of the adhesive 41 layer is between 0.1 mm and 10 mm, and is configured so that the reflectors 43 are at a slight angle with respect to another. This is accomplished by making the adhesive layers wedge-shaped. Typically, especially with a small number of reflectors (such as five or less), the axis of rotation of the wedge angles are parallel. For a large number of reflectors, such as six or more, there can be two axis of rotation (i.e., a compound angle can be formed, as shown in FIG. 12) allowing for the PV-cells to be offset from one another in a second direction. The amount of wedge angle between the reflectors 43 can be between 0.1° and 10°, and can be the same for each adhesive layer 43 or vary amongst the adhesive layers.

The PV-cells 52, 54, 56, 58, and 60 as shown in FIG. 3 are placed in the focal points of the converging light 42, 44, 46, 48, and 50 respectively of the spectrally separated light band that they are most responsive to. The PV-cells are each typically a single junction PV-cell, although they can be double or even triple junction cells. The PV-cells 52, 54, 56, 58, and 60 are typically square or rectangular in shape, and can range in size from 2 mm×2 mm up to 20 mm×20 mm. Said PV-cells are constructed for optimized operation under concentrated light illumination. Said PV-cells also have an antireflective coating installed on the input face of the cell to reduce the amount of light that is reflected from the cell, and to increase the amount of light transmitted into the cell. The antireflective coatings should be optimized for the range of wavelengths in the spectrally limited band of light that is incident on each of the cells.

In operation solar radiation 1 enters the condensing fresnel lens 30 which, being a positive lens causes the solar illumination to converge with a convergence envelope 32. A reflector assembly 40 is placed within the convergence envelope 32 so that substantially all of the light within the envelope 32 is incident on the reflector assembly 40. As shown in FIG. 4, a representative ray 32A of the convergence envelope 32 is incident on the first reflecting layer 45A which causes a first spectral band of light, λ_{A}, to be reflected. Reflecting layer 45A transmits all other spectral bands of light λ_{B} through λ_{E}. A light ray 47A that is reflected by the first reflecting layer 45A lies within a reflected light convergence envelope 42 that comes to a focus on a PV-cell 52 that is particularly responsive to the wavelength band λ_{A} contained within the converging light rays 47A.

Light bands λ_{B} through λ_{E} of representative ray 32A that are not reflected by the first reflecting layer 45A are transmitted through the first substrate 43A and adhesive layer and become incident on the second reflecting layer 45B. It is important to note that if the refractive index of the adhesive 41 is substantially the same as the refractive index of the substrate 43A then the transmitted ray will not change in direction due to refraction as it passes from substrate 43A into the adhesive material 41, and the fresnel reflections (which cause stray light and reduce system efficiency) are minimized. At the second reflecting layer 45B a second spectral band of light, λ_{B}, is reflected and all remaining spectral bands of light λ_{C} through λ_{E} are transmitted. A light ray 47B that is reflected by the second reflecting layer 45B lies within a reflected light convergence envelope 44 that passes back through the first substrate 43A and first reflecting layer 45A and comes to a focus on a PV-cell 54 that is particularly responsive to the wavelength band λ_{B} contained within the converging light rays 47B.

Light bands λ_{C} through λ_{E} of representative ray 32A that are not reflected by the first and second reflecting layers 45A and 45B are transmitted through to the third reflecting layer 45C. It is important to note that if the refractive index of the adhesive 41 is substantially the same as the refractive index of the substrate 43B then the transmitted ray will not change in direction due to refraction as it passes from substrate 43B into the adhesive material 41, and the fresnel reflections (which cause stray light and reduce system efficiency) are minimized. At the third reflecting layer 45C a third spectral band of light, λ_{C}, is reflected and all remaining spectral bands of light, λ_{D} and λ_{E} are transmitted. A light ray 47C that is reflected by the third reflecting layer 45C lies within a reflected light convergence envelope 46 that passes back through the first and second substrates 43A and 43B and first and second reflecting layers 45A and 45B, and comes to a focus on a PV-cell 56 that is particularly responsive to the wavelength band λ_{C} contained within the converging light rays 47C.

Light bands λ_{D} and λ_{E} of representative ray 32A that are not reflected by the first, second, and third reflecting layers 45A, 45B, and 45C are transmitted through to the fourth reflecting layer 45D. It is important to note that if the refractive index of the adhesive 41 is substantially the same as the refractive index of the substrate 43C then the transmitted ray will not change in direction due to refraction as it passes from substrate 43C into the adhesive material 41, and the fresnel reflections (which cause stray light and reduce system efficiency) are minimized. At the fourth reflecting layer 45D a fourth spectral band of light, λ_{D}, is reflected and the remaining spectral band of light, λ_{E}, is transmitted. A light ray 47D that is reflected by the fourth reflecting layer 45D lies within a reflected light convergence envelope 48 that passes back through first, second, and third substrates 43A, 43B, 43C and first, second, and third reflecting layers 45A, 45B, and 45C, and comes to a focus on a PV-cell 58 that is particularly responsive to the wavelength band λ_{D} contained within the converging light rays 47D.

Finally, light band λ_{E} of representative ray 32A that is not reflected by the first, second, third, and fourth reflecting layers 45A, 45B, 45C, and 45D are transmitted through to the fifth reflecting layer 45E. It is important to note that if the refractive index of the adhesive 41 is substantially the same as the refractive index of the substrate 43D then the transmitted ray will not change in direction due to refraction as it passes from substrate 43A into the adhesive material 41, and the fresnel reflections (which cause stray light and reduce system efficiency) are minimized. At the fifth reflecting layer 45E the last spectral band of light, λ_{E}, is reflected, and substantially none of the light that the PV-cells 52, 54, 56, 58, and 60 are responsive to and contained within the solar radiation 1 is transmitted. A light ray 47E that is reflected by the fifth and final reflecting layer 45E lies within a reflected light convergence envelope 50 that passes back through first, second, third, and fourth substrates 43A, 43B, 43C, and 43D, and first, second, third, and fourth reflecting layers 45A, 45B, 45C, and 45D, and comes to a focus on a PV-cell 60 that is particularly responsive to the wavelength band λ_{E} contained within the converging light rays 47E.

Accordingly, there is set forth herein an apparatus for converting solar energy, the apparatus comprising an optical element for converging solar radiation; and a reflector assembly receiving light transmitted by the optical element and including a first substrate having a first reflector and a second substrate spaced apart from the first substrate and having a second reflector, the first reflector being adapted to reflect a first spectral band of light transmitted by the optical element, the first reflector being adapted to transmit one or more spectral band of light outside of the first spectral band of light, the second reflector being adapted to reflect a second spectral band of light transmitted by the optical element, the second reflector being adapted to transmit one or more spectral band of light outside of the second spectral band, wherein the reflector assembly is configured so that a reflector of the first and second reflector transmits light reflected from the remaining of the first and second reflector, wherein the reflector assembly further includes adhesive material disposed between the first substrate and the second substrate, the adhesive material bonding the first substrate and the second substrate; wherein the apparatus for converting solar energy further comprises a first photovoltaic cell and a second photovoltaic cell, wherein the first photovoltaic cell is disposed to receive light reflected from the first reflector, wherein the second photovoltaic cell is disposed to receive light reflected from the second reflector, wherein the first photovoltaic cell is particularly responsive to the first spectral band of light, and wherein the second photovoltaic cell is particularly responsive to the second spectral band of light.

There is also accordingly set forth herein an apparatus for obtaining energy from a polychromatic radiant energy source, the apparatus comprising a concentrator; a spectral separator comprising a first surface located on a first substrate, the first surface being adapted to reflect a first spectral band of light received from the concentrator, the first surface being adapted to transmit one or more spectral band of light outside of the first spectral band of light; a second surface located on a second substrate, the second substrate being spaced apart from the first substrate, wherein the second surface is adapted to reflect a second spectral band of light through the first substrate; and a layer of material disposed between the first substrate and the second substrate, the layer of material being in contact with the first substrate and the second substrate; wherein the layer of material transmits light in the second spectral band and has an index of refraction matched to an index of refraction of the first substrate, and wherein the index of refraction of the layer of material is further matched to an index of refraction of the second substrate; a first light receiver disposed to receive light reflected from the first surface; a second light receiver disposed to receive light reflected from the second surface, wherein the first light receiver is particularly responsive to the first spectral band of light, and wherein the second light receiver is particularly responsive to the second spectral band of light.

There is also set forth herein an apparatus for converting solar energy, the apparatus comprising an optical element for converging solar radiation; and a reflector assembly receiving light transmitted by the optical element and including a first substrate having a first reflector and a second substrate spaced apart from the first substrate and having a second reflector, the first reflector being adapted to reflect a first spectral band of light transmitted by the optical element, the first reflector being adapted to transmit one or more spectral band of light outside of the first spectral band of light, the second reflector being adapted to reflect a second spectral band of light transmitted by the optical element, the second reflector being adapted to transmit one or more spectral band of light outside of the second spectral band, wherein the reflector assembly is configured so that a reflector of the first and second reflector transmits light reflected from the remaining of the first and second reflector, wherein the reflector assembly further includes a layer of material disposed between the first substrate and the second substrate, the layer of material being in contact with the first substrate and the second substrate, wherein the layer of material has an index of refraction matched to an index of refraction of the first substrate; and wherein the apparatus for converting solar energy further comprises a first photovoltaic cell and a second photovoltaic cell, wherein the first photovoltaic cell is disposed to receive light reflected from the first reflector, wherein the second photovoltaic cell is disposed to receive light reflected from the second reflector, wherein the first photovoltaic cell is particularly responsive to the first spectral band of light, and wherein the second photovoltaic cell is particularly responsive to the second spectral band of light. There is also set forth herein the described adhesive wherein the apparatus is adapted so that for contact with the first and second substrate, the layer of material bonds the first and second substrate.

While the preceding description is based upon a system in which five spectral bands are created and brought to a focus on five PV-cells, in actuality the system is scalable and any number from two to ten, or even up to twenty or more spectral bands can be made and brought to a focus on a like number of PV-cells.

There is set forth herein an apparatus for obtaining energy from a polychromatic radiant energy source, the apparatus comprising a fresnel lens concentrator, a spectral separator comprising a first surface treated to reflect a first spectral band of light received from the fresnel lens concentrator toward a first focal region; and to transmit one or more other spectral bands; a plurality of additional surfaces spaced apart from the first surface and from each other, wherein the plurality of surfaces are treated to reflect different spectral bands of light back through the first surface and toward focal regions that are spaced apart from the first focal region and from each other; a first light receiver, a plurality of additional light receivers, wherein the first light receiver is located at the first focal region for receiving the first spectral band and the plurality of additional light receivers are located at a focal region for receiving the spectral band of light that each is most responsive to.

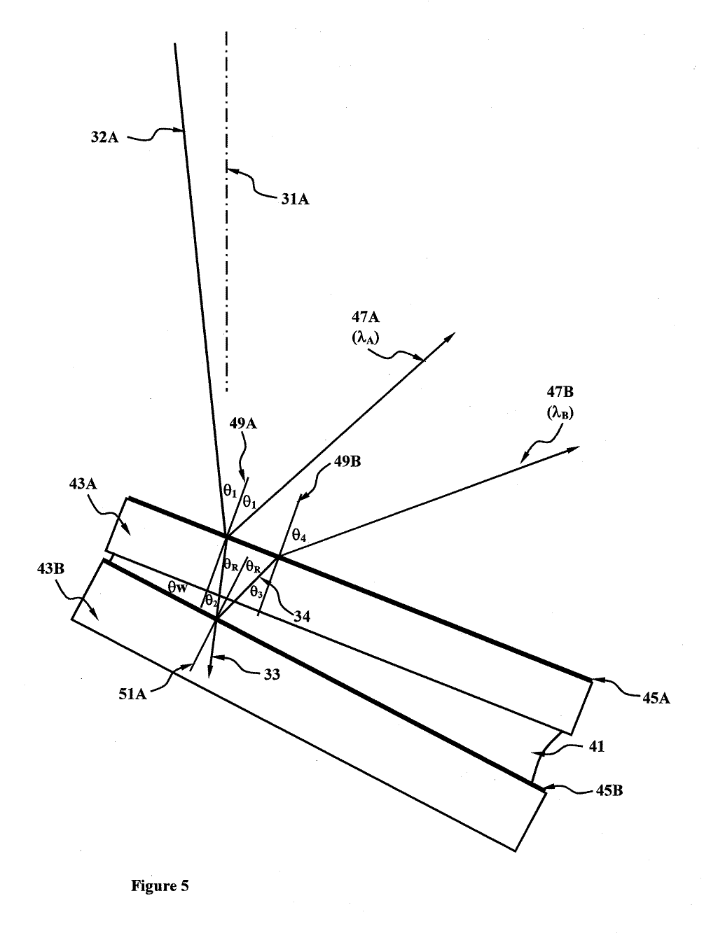

FIG. 5 is a side-view illustration of the first and second substrates 43A and 43B, the upper adhesive layer 41, and several exemplary rays 32A, 33, 47A, and 47B. Note that the upper adhesive layer 41, like all adhesive layers has a wedge angle, θ_{w}, and both surfaces of both substrates 43A and 43B are planar and do not have optical power in this exemplary analysis. Furthermore, the refractive index of the adhesive layer 41 is assumed to be substantially the same as the refractive index of the substrates 43A and 43B. While this configuration is beneficial for analyzing the paths of rays such as rays 33, 47A and 47B, other configurations are possible, such as where the upper surfaces 45A and 45B of substrates 43A and 43B do have optical power or are microstructured with a fresnel surface.

Continuing with FIG. 5, exemplary input sun ray 32A is incident on upper surface 45A of substrate 43A, at an angle of incidence of θ₁ with respect to the surface normal 49A. Due to the Law of Reflection, the angle of existence of ray 47A, which contains only wavelengths of wavelength band λ_{A}, is also θ₁ with respect to the surface normal 49A. Light of exemplary ray 32A that is not reflected at surface 45A (i.e., that does not contain wavelengths of band λ_{A}) is transmitted into substrate 43A at an angle of θ₂ with respect to the surface normal 49A, which can be computed from Snell's Law as θ₂=arcsin(sin(θ₁)/n), where n is the refractive index of the substrate 43A, and it was assumed that the refractive index of the medium that ray 32A propagates through is unity. Transmitted ray 33 is then incident on surface 45B (which is reflective to wavelength band λ_{B}) at an of θ_{R} with respect to the surface normal 51A of surface 45B. Due to the Law of Reflection, the angle of the reflected ray 34 at surface 45B is also θ_{R} with respect to the surface normal 51A. Reflected ray 34, which contains wavelengths only of wavelength band λ_{B}, then propagates through the adhesive layer 41 and the substrate 43A until it reaches the upper surface 45A of the first substrate 43. A reflected ray 34 is incident on surface 45A at an angle of incidence of θ₃ with respect to surface normal 49B. By inspection, θ₃=θ_{R}+θ_{W}=θ₂+2θ_{W}. Finally, reflected ray 34 refracts through surface 45A in accordance with Snell's Law at an angle of θ₄ with respect to the surface normal 49B, wherein θ₄=arcsin [n×sin(θ₃)]=arcsin [n sin(θ₂+2θ_{W})]. Substituting in θ₂=arcsin(sin(θ₁)/n) creates an expression that determines the relationship between the output angle θ₄ as a function of θ₁ and θ_{W}. This expression is:

θ₄=arcsin {n sin(arcsin [sin(θ₁)/n]+2θ_{W})}.

A table of values, as well as PV-cell lateral separations for a variety of values for θ₁ and θ_{W} are provided in Table 1, below (a substrate refractive index of 1.50 was assumed). The lateral PV-cell separation assumes a PV-cell to reflector assembly distance of 100 mm.

| θ₁ | θ_{W} | θ₄ | PV-cell Separation |
|---|---|---|---|
| 0° | 1° | 3.001° | 5.2 mm |
| 0° | 2° | 6.006° | 10.5 mm |
| 10° | 1° | 13.03° | 5.5 mm |
| 10° | 2° | 16.09° | 11.2 mm |
| 20° | 1° | 23.13° | 6.3 mm |
| 20° | 2° | 26.30° | 13.0 mm |
| 30° | 1° | 33.30° | 8.0 mm |
| 40° | 2° | 36.69° | 16.8 mm |

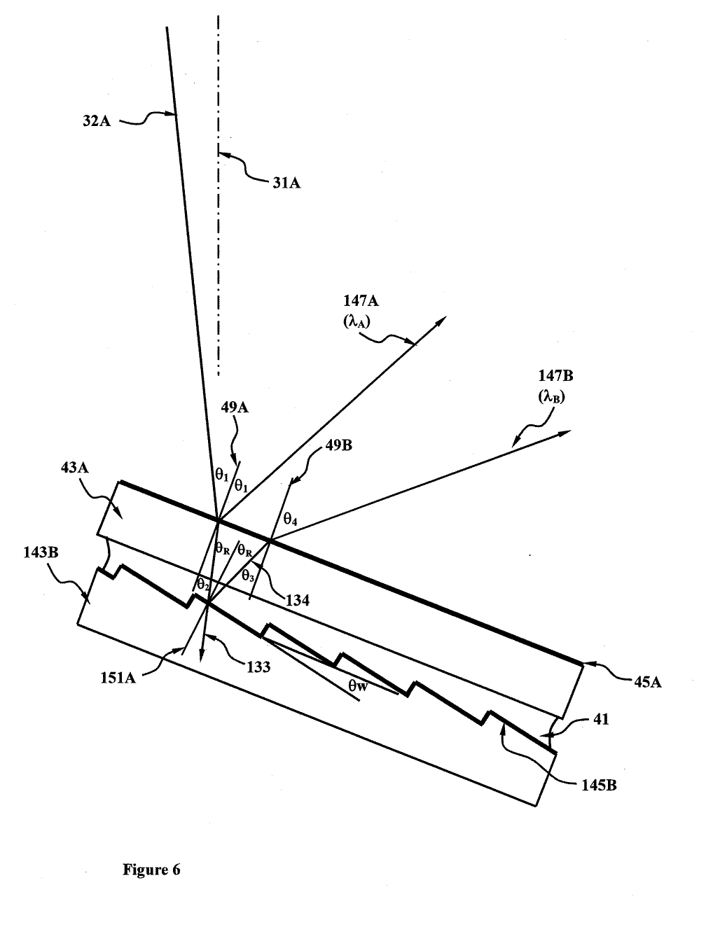

FIG. 6 shows a partial representation of an alternate embodiment of the present invention in which one or more of the planar reflective surfaces 45B, 45C, 45D, and 45E have been replaced by a sawtooth fresnel microstructures, of which only 145B is shown. In this configuration the substrates 43A, 143B, 143C (not shown), 143D (not shown) and 143E (not shown) are all substantially parallel with one another, and the angular surface rotation, or wedge angle θ_{w}, is accomplished by the presence of the sawtooth microstructure whose slope surface is also at angle θ_{w}. The raytrace analysis therefore proceeds substantially the same as described above in connection with FIG. 5. Alternately there can be wedge in the adhesive layer 41 with an accompanying change in the prescription of the fresnel microstructure. This can be beneficial as a means to reduce the depth of the fresnel draft surfaces (light that is incident on a draft surface is often lost to the system thereby reduces system efficiency), yet maintain the advantages of a non-planar surface prescription for controlling the direction and wavefront quality of the reflected light.

An important feature of the microstructured configuration shown in FIG. 6 occurs when the refractive index of the adhesive 41 is substantially the same as the refractive indices of the substrates 43A and 143B. In this case all rays that cross the surface boundaries, such as from a substrate to the adhesive or from an adhesive layer into a substrate, are unchanged in direction due to Snell's Law. This will occur for any ray angle of incidence, and for any microstructure slope angle θ_{w}. This is beneficial because the change in direction of the rays due to reflection at the reflective surfaces 454B, 45C, etc., can be decoupled from the transmitted ray directions through any reflector assembly embodiment described herein. It is also beneficial because a refractive index match will substantially eliminate fresnel reflections at the surface and improve light throughput as discussed earlier.

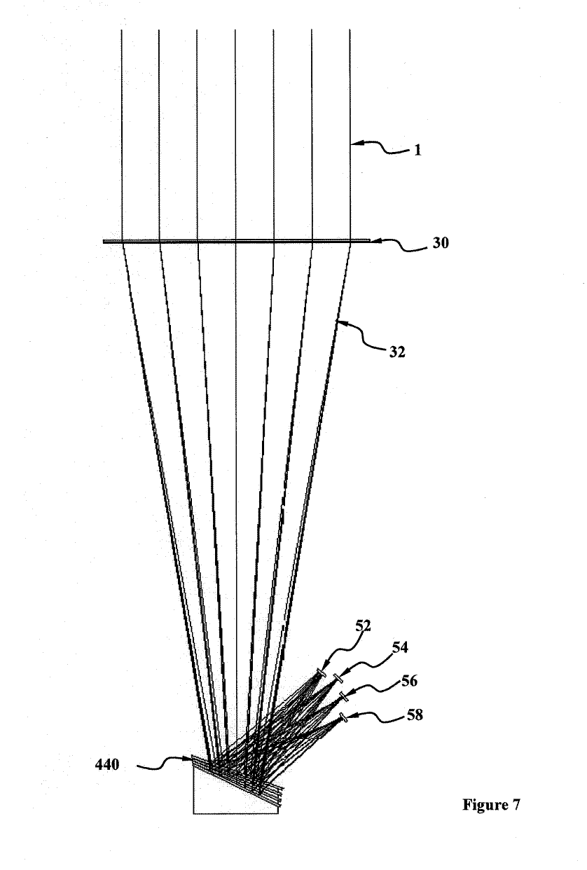

FIG. 7 is a diagram showing a side-view image of the output created by the TracePro raytracing and optical analysis CAD program. As with previous descriptions, sunlight 1 is incident on the input surface of a fresnel lens 30 which causes the incident sunlight to condense with convergence envelope 32. The converging light is incident on a four-reflector reflector assembly 440, wherein all four reflectors are installed on plano-plano substrates that are oriented with a small wedge angle between them. The reflected rays become angularly and spatially separated, as well as spectrally, and each spectral band of converging light is brought to a focus onto a PV-cell whose spectral response is particularly well-matched to the wavelengths of light incident upon it. Note also in FIG. 7 the outboard rays (the rays at the edge of the converging light 32) as they leave the condensing fresnel lens 32. Specifically, it can be seen that these rays, as they propagate a distance, broaden and separate due to the dispersion of the fresnel lens. This dispersive phenomenon is well understood, wherein the focal length of the shorter wavelengths is shorter than the focal length of the longer wavelengths. This effect is discussed later in connection with PV-cell locations.

In the concentrator depicted in FIG. 7, the optical model entered into TracePro utilized a square fresnel lens 30 that is 250 mm on a side and has a focal length of 640 mm. The pitch of the fresnel microstructure is 1 mm, although generally a smaller pitch is used and 1 mm was selected only to reduce the number of surfaces and complexity of the optical model. The distance from the fresnel lens 30 to the first surface 45A is 500 mm, and each reflector substrate is 90 mm×90 mm×2 mm thick. The optical model illuminated the fresnel lens 30 with broadband light containing wavelengths between 400 nm and 1800 nm. In the optical model the reflective layer on the first reflective surface 45A reflected wavelengths between 350 nm and 680 nm (for the InGaP PV-cell), the reflective layer on the second reflective surface 45B reflected wavelengths between 681 nm and 890 nm (for a GaAs PV-cell), the reflective layer on the third reflective surface 45C reflected wavelengths between 891 nm and 1100 nm (for a silicon PV-cell), and the reflective layer on the fourth reflective surface 45D reflected wavelengths between 1101 nm and 1800 nm (for a Germanium PV-cell). The four reflector substrates were rotated about four parallel axis of rotation, wherein the first reflector substrate 43A was rotated 20° from horizontal, the second reflector 43B was rotated 22°, the third reflector 43C was rotated 24°, and the fourth reflector 43D was rotated 26° about their respective axis of rotation. The distance from the reflector assembly 440 to the PV-cells varied from cell to cell, but averaged 120 mm. The PV-cells are all 10 mm×10 mm in area, and are situated so they are square with the incident converging spectrally separated light bands.

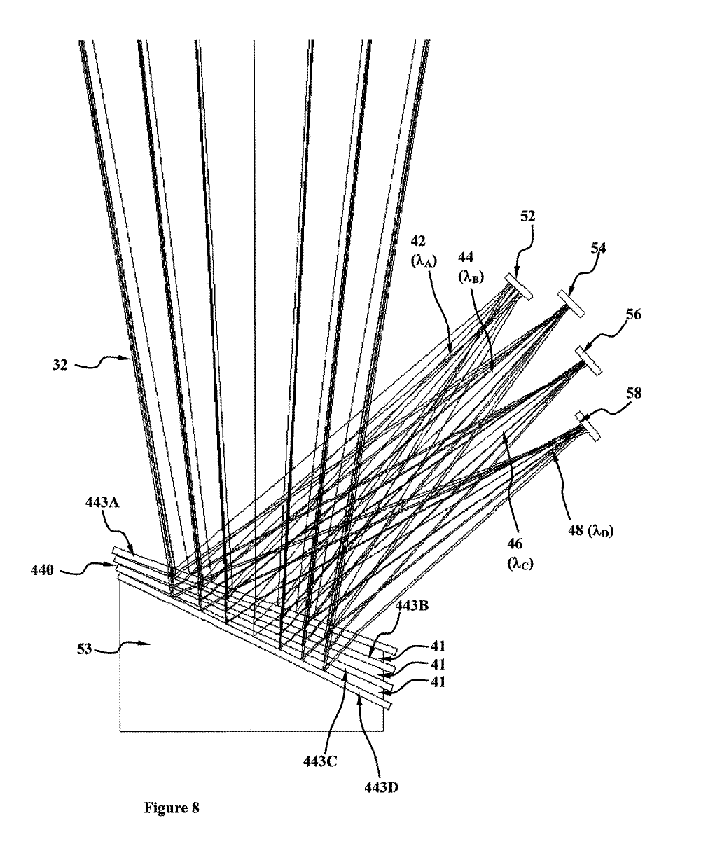

Note that in FIG. 7 the location of the PV-cells 52, 54, 56, and 58 are not located along a line, but instead are offset from one another (although are coplanar in the “plane of the paper”). This is even more apparent in FIG. 8, which is magnified view of the reflector assembly 440 and exemplary ray paths. The PV-cell distance offsetting is due to two phenomena: First the focal length of the fresnel lens 30 varies with wavelength due to the dispersive properties of the material that it is made from, such that the shorter wavelengths have a shorter focal length than the longer wavelengths. This is the reason why the short-wavelength band of converging light 42 comes to focus closer to the reflector assembly 440 than its neighboring band of converging light 44 which contains longer wavelengths. Therefore the short-wavelength responsive PV-cell 52, being placed at the focal location of converging light 42 is closer to the reflector assembly 440 than its neighboring PV-cell 54 which is responsive to the next longest wavelength band and placed at the focal location of converging light band 44. Secondly, the longest wavelength band of light λ_{D} must traverse through the upper three substrates and adhesive layers, which has a longer optical path length than the second longest wavelength band of light λ_{C} which must traverse only two substrates and two adhesive layers. Therefore, the longest wavelength band of converging light 48 will be brought to a focus closer to the reflector assembly 440 than the second longest converging band of light 46, and since the PV-cells are located at the focal points, the location of PV-cell 58 (responsive to the longest wavelength band λ_{D}) will be closer to the reflector assembly than the PV-cell 56 which is responsive to the second longest wavelength band of light λ_{C}.

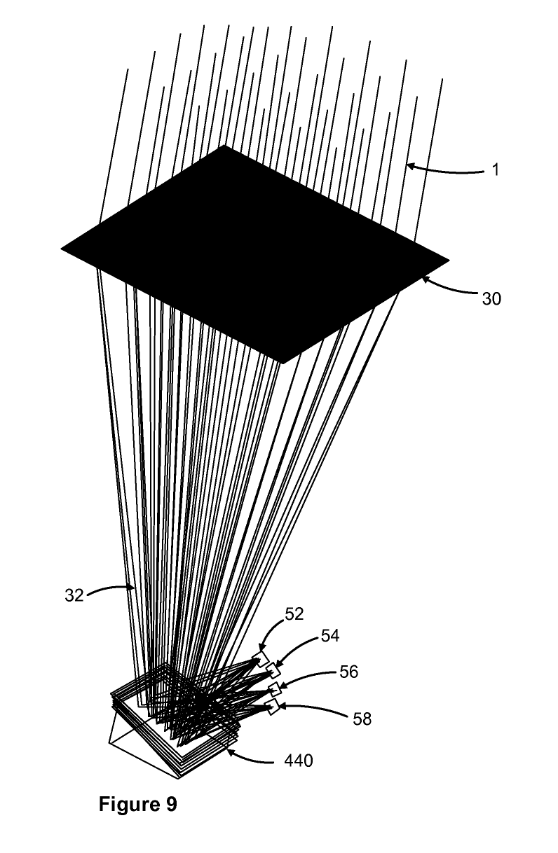

FIG. 9 shows an isometric view of the same optical configuration described in connection with FIG. 8 and FIG. 7. It can be gleaned from this view that while the four PV-cells 52, 54, 56, and 58 are not collinear, they are coplanar which can be beneficial as it allows for mounting of the PV-cells onto a unitary mounting block which simplifies both the management of the heat generated by the PV-cells as well as simplifying the electrical connections as they would all inherently share a common electrical terminal at the unitary mounting block.

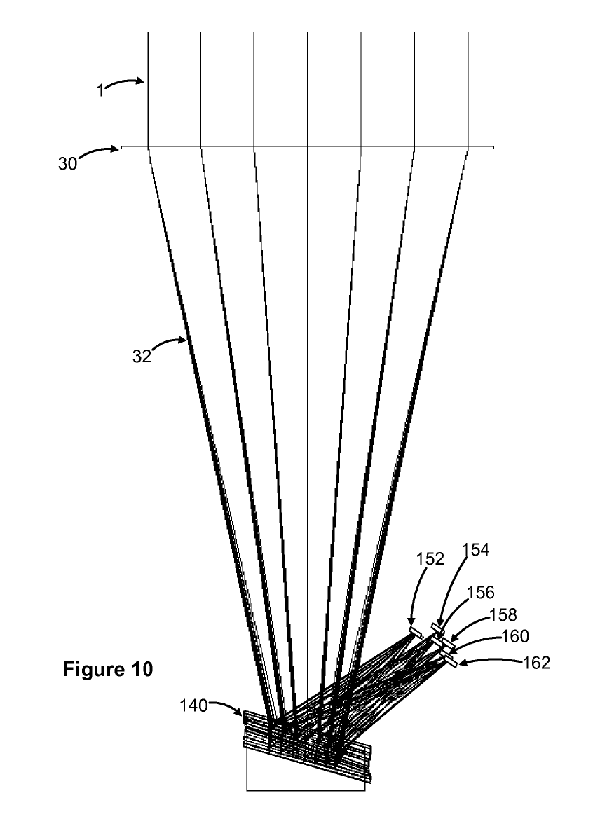

It has been previously noted that, in general, the greater the number of spectral splits and accompanying PV-cells the greater the overall efficiency of the converter will be. To that end a side view image of the TracePro raytrace output of a six-split six-PV-cell converter is shown in FIG. 10. In this TracePro model the fresnel lens 30 and illumination 1 is the same as the four-cell configuration described above in connection with FIGS. 7, 8, and 9. However, the reflector assembly 140 has been changed to include two additional mirrors. Because of this, two additional PV-cells must be included, and the wavelength groupings must also change accordingly.

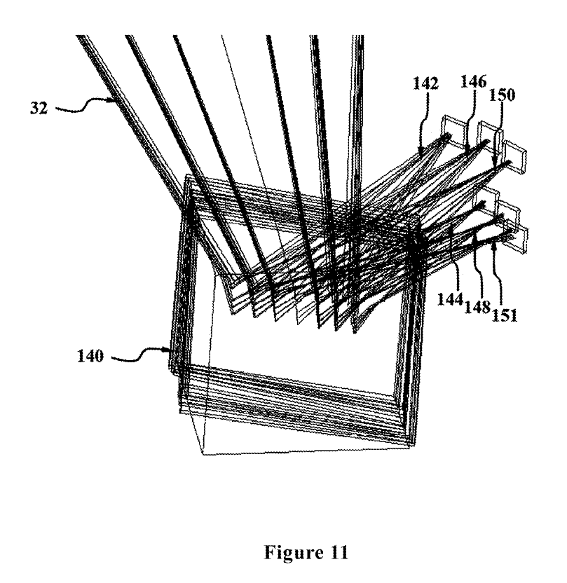

FIG. 11 shows an oblique image of a magnified view of the augmented reflector assembly 140, the six converging light bands (each containing a distinct and unique band of wavelengths) 142, 144, 146, 148, 150, and 151, and the six PV-cells that they converge onto. Notice that the light convergence envelope 32 and optical axis 31 of the fresnel lens is unchanged from before. However, the reflector assembly 140 has been changed, or enhanced, further by the addition of a compound angle on the reflector (or reflector substrate) positioning with respect to the optical axis 31. If a non-compound configuration was used, then all six PV-cells would necessarily be located in extremely close proximity to one another in a single plane. In the compound angle configuration, in which half of the reflective substrates are angled with second angle θ_{wc}/2 and the other half are angled with second angle −θ_{wc}/2 (in addition to the first angle rotations in which the axis of rotation are parallel), then the six PV-cells will lie in two separate planes, and will be adequately spaced apart.

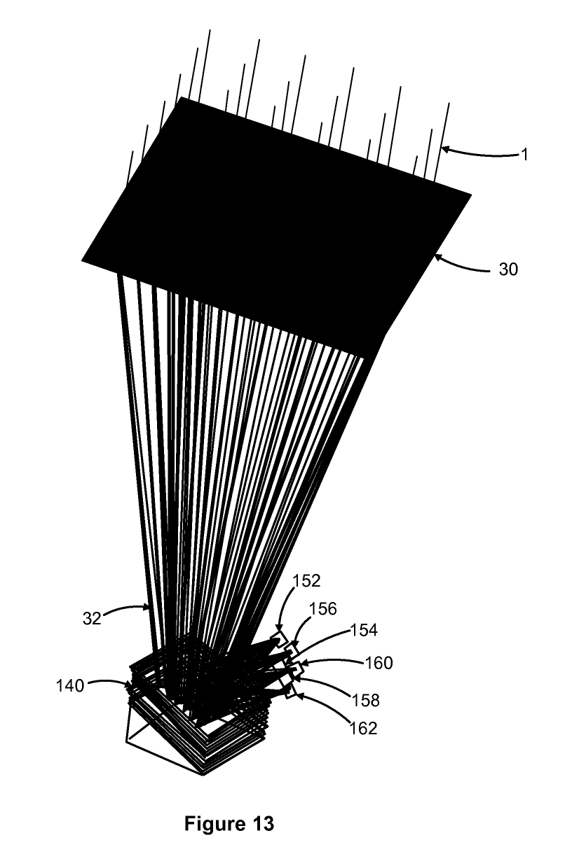

FIG. 12 is an end-view of the reflector assembly 140 showing the second angle of the reflectors θ_{wc} and the relationship of the various reflectors and PV-cells comprising the converter. FIG. 13 is an isometric view of the TracePro raytrace output of the reflector assembly 140 having second angle θ_{wc} which offers an additional perspective of the six-cell embodiment.

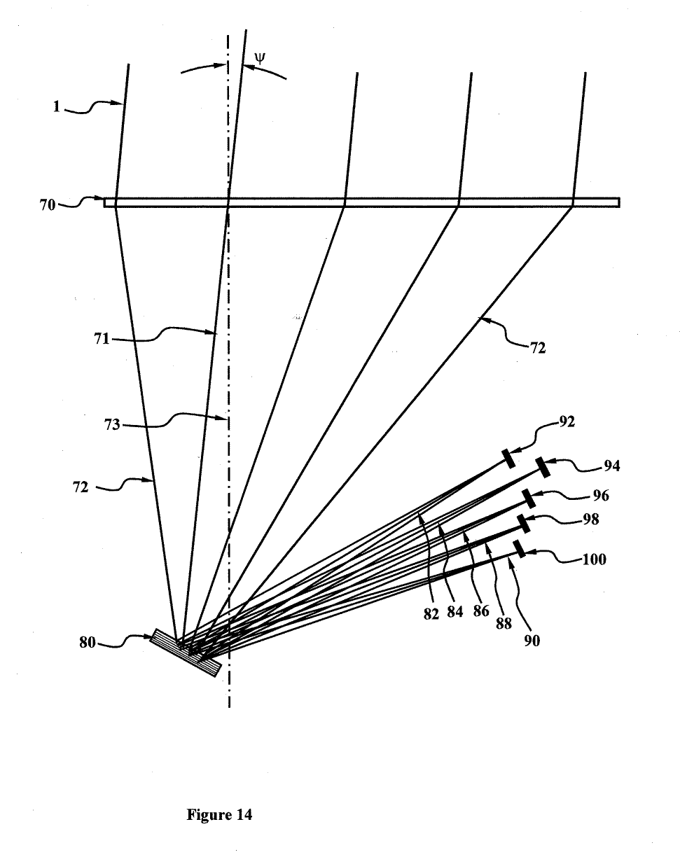

Heretofore the converters have all been configured to operate in a way wherein the reflector assembly 40, 140, 240, 440, 540, or 80 have been located on the optical axis 31 or 31A of the condensing fresnel lens 30. In actuality the reflector assembly can be located off the optical axis as shown in FIG. 14, which has the advantage of providing more room within the concentrator for the placement of the PV-cells within the converter's housing. In this off-axis configuration, sunlight 1 is incident on the fresnel lens 70 at angle ψ with respect to the fresnel lens's optical axis 73. This causes the envelope of converging light 72 to be directed away from the optical axis 73, allowing for the reflector assembly 80 to be located off the optical axis 73. Note that since the reflector assembly 80 is positioned further to the left in FIG. 14, there is now more room for PV-cells 92, 94, 96, 98, and 100 to be mounted and positioned to the right of the reflector assembly 80.

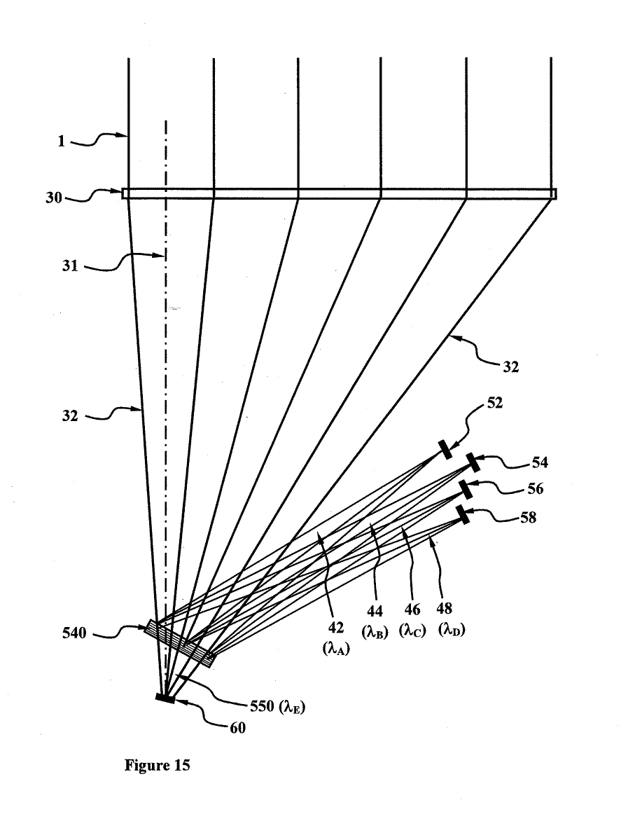

An alternate configuration of the present invention is shown in FIG. 15, in which the lowermost reflector and substrate is eliminated. In this case the last band of wavelengths λ_{E} passes through the entire reflector assembly 540. By virtue of the fact that the exiting light 550 it is still converging, it can be brought to a focus on the same PV-cell 60 that is highly responsive to the band of wavelengths (λ_{E}) contained in converging envelope 550. This configuration has the obvious benefit of a simplified reflector assembly 540, but increased mounting and wiring complexity due to the fact that PV-cell 60 is now separated from the remaining group of PV-cells 52, 54, 56, and 58. It is worthwhile to point out that the lowermost surface of the reflector assembly 540 (i.e., that surface that converging light 550 exits through) should be provided with an antireflective treatment so that fresnel reflections at the surface is minimized and the amount of optical flux contained in the converging light envelope 550 is maximized.

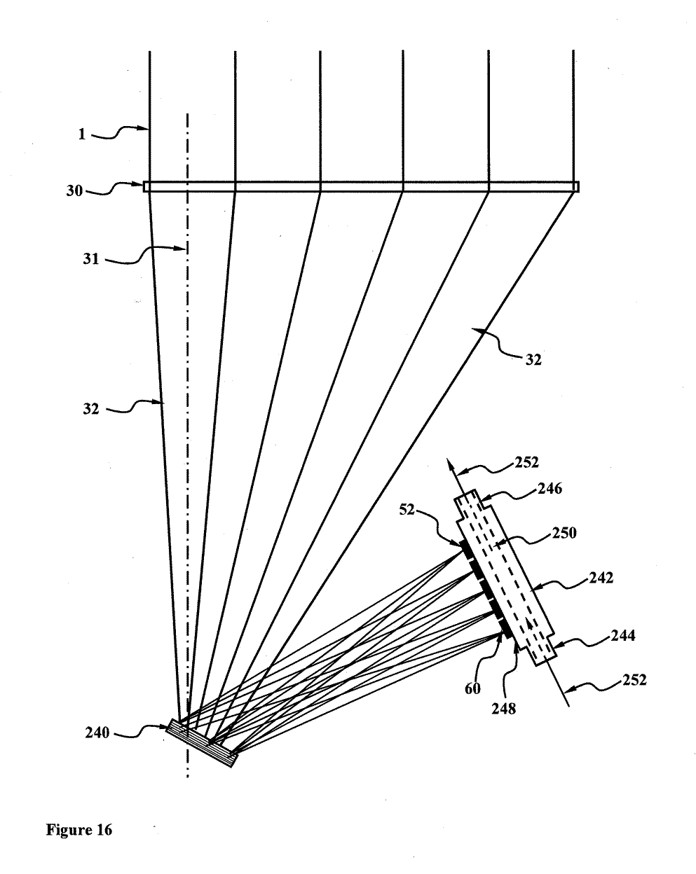

FIG. 16 illustrates yet another embodiment wherein the PV-cells are all located in proximity to one another, and located such that the rear surfaces (i.e., those surfaces on the side of the PV-cell opposite the side being illuminated with converging light) of the PV-cells are all coplanar. Such a coplanar arrangement significantly simplifies the configuration of the mounting block 242 that the PV-cells, 52 and 60 for example, that the PV-cells are attached to. Such mounting blocks 242 can be provided with a cooling channel 250 with an inlet port 244 and outlet port 246 through which a cooling fluid 252 can be caused to flow. The cooling fluid 252 is at a cooler temperature than the PV-cells, and therefore provides a means of thermal management and cooling of the PV-cells by way of conductive heat transfer from the PV-cells into the mounting block 242 and then convection heat transfer from the mounting block 242 to the fluid 252. Note that since the thickness of the mounting block 242 from its front face 248 to the cooling channel 250 (by virtue of the fact that the rear side of the PV-cells are coplanar and mounted on planar surface 248) then the PV-cell cooling is uniform and all PV-cells operate at a uniformly cool temperature.

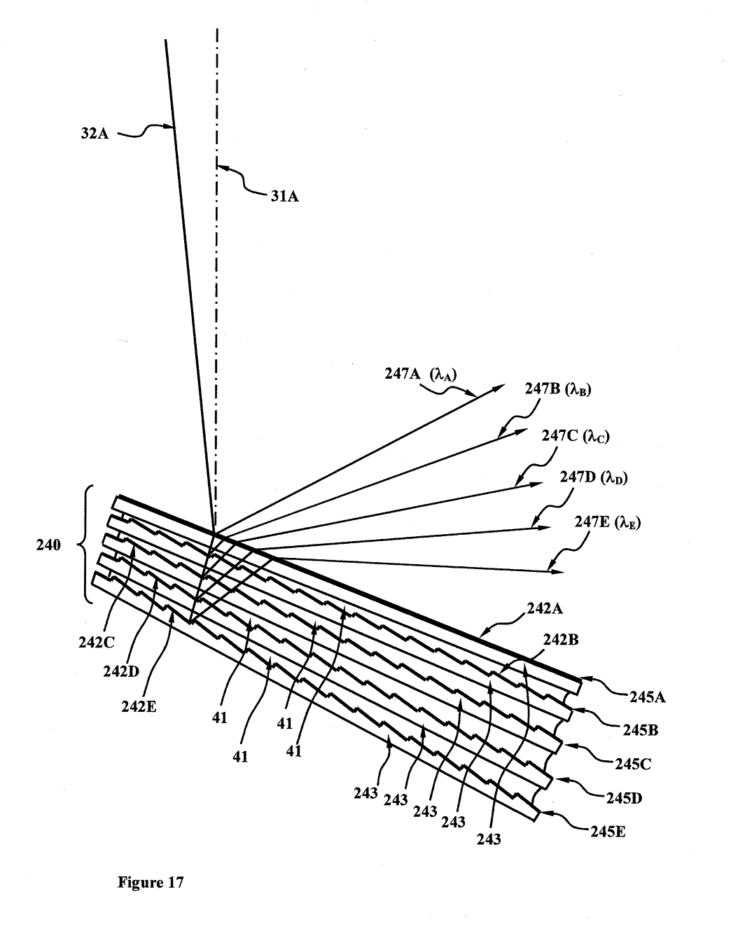

However, configuring the optics such that the rear surfaces of all PV-cells depicted in FIG. 16 lie in the same plane is not straightforward. The best way to accomplish this is by providing one or more reflective surfaces within the reflector assembly 240 with optical power which causes the focal positions of the respective converging bands of light to be changed. Said optical power can be achieved by making the reflecting surface curved, or by making it microstructured, with, for example, a fresnel microstructure as shown in FIG. 17.

FIG. 17 is a side-view of a five-reflector reflector assembly 240 in which individual reflectors 245B, 245C, 245D, and 245E are all installed onto substrate 243 that each have fresnel microstructure 242B, 242C, 242D, and 242E installed or otherwise molded onto them. Note that the first reflective surface 245A is installed onto a planar first surface 242A which does not have optical power, although first surface 242A could instead be non-planar and have optical power as needed to bring the focal location of the first spectral band of light (λ_{A}) into a location that is collinear with the other four focal positions such that the rear surface of the PV-cells are coplanar at the planar surface 248 of the mounting block 242. The optical prescription of the surfaces (whether curved or fresnel microstructured) will generally vary from reflector to reflector due to the variation in focal positions with spectral band wavelengths which was described earlier.

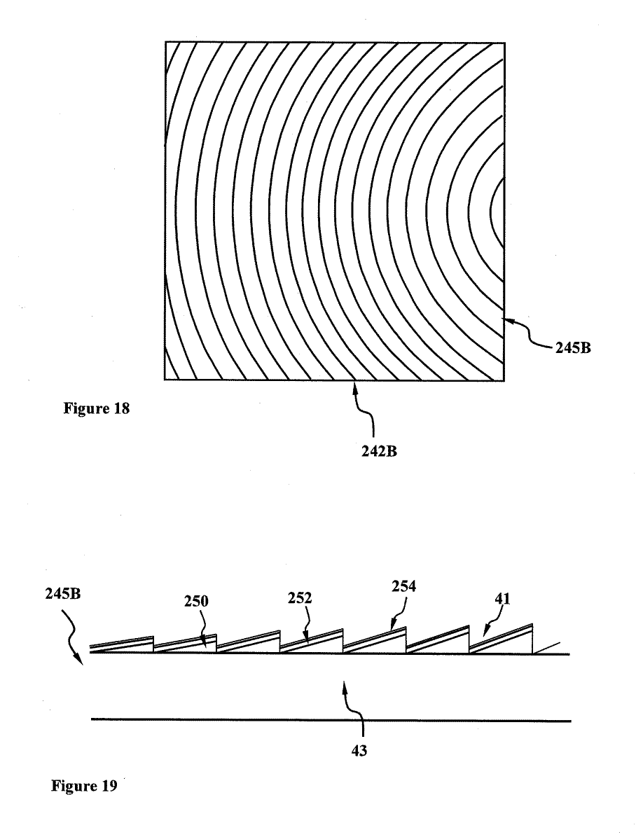

A plan view of one reflector component 242B, having reflector 245B, is illustrated in FIG. 18. Note that the fresnel grooves are curved, and may be circular and concentric about an axis of rotation (not shown), or they may be curved and non-concentric. The grooves may even be linear across the face of the reflector component 242B. The slope angle of a slope surface of a groove may be constant over the length of a groove, or it may vary. If the surface of a reflector component is curved, it can be spherical, or aspherical, and if aspherical it can have an axis of rotation or be non-rotationally symmetric.

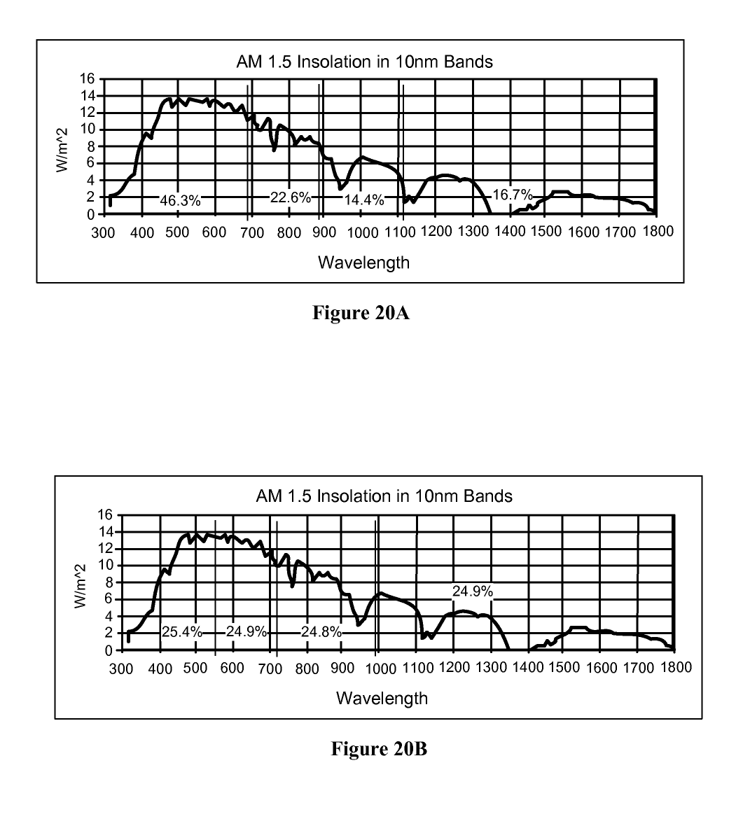

FIG. 19 shows a side-view of a representative fresnel reflector of the reflector assembly 40 or 240. One set of preferred materials comprising the fresnel reflector 40 or 240 is where the substrate 43 is composed of a glass material and the microstructure 250 installed on the substrate is a silicone. It is well-known that these two materials are long-lived and durable, and degrade very slowly (if at all) when exposed to solar radiation. However, silicone materials are elastic and flexible, whereas most dielectric reflectors 254 are inelastic and inflexible, and furthermore tend to be thin and brittle. Installing such a dielectric reflector 254 directly onto a silicone microstructure 250 creates a material property mismatch, which can cause the dielectric reflector 254 to crack, thereby reducing the efficiency of the reflector 254. To remedy this, a relatively thick layer of intermediate material 252 can be installed onto the elastic microstructure 250 over which is placed the fragile dielectric reflector 254. The intermediate material 252 can be made from SiO₂ or SiO, is substantially transparent and inexpensive to install. Furthermore, being relatively thick and rigid, the intermediate layer 252 can support the brittle reflector 254 so that it does not crack or break as it rests on the elastic silicone microstructure 250.

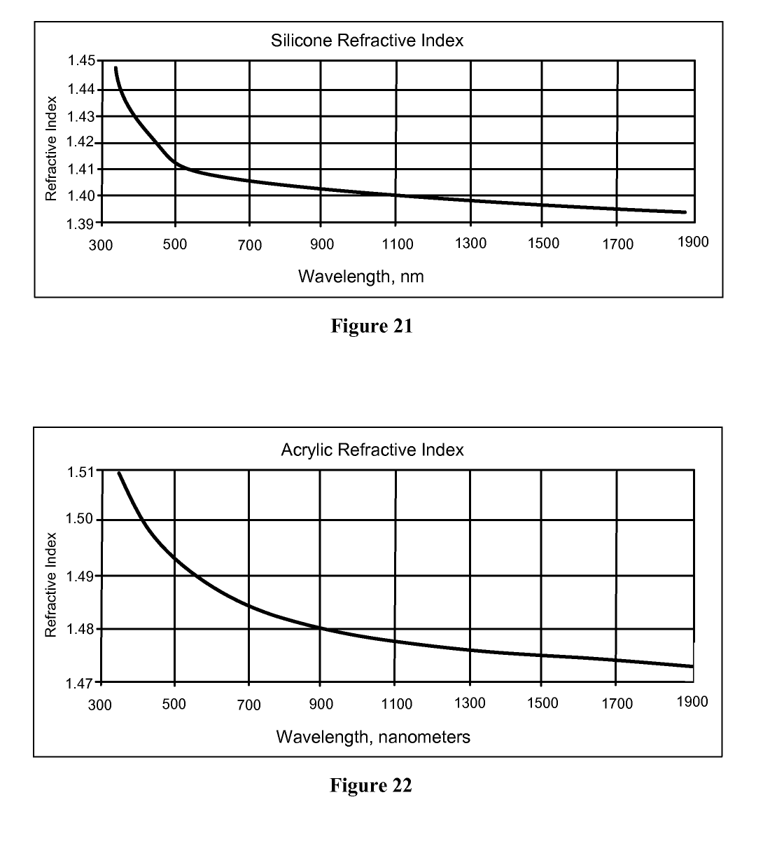

As mentioned earlier, the number of spectral bands created by the reflector assembly can be from as few as two to more than ten, with three to six bands being the most practical from a manufacturability and cost/watt viewpoint. The range of wavelengths within each spectral band can be determined by the spectral response curves of the PV-cells, such that each PV-cell is illuminated with light from the highest portions of their responsivity curves. If four PV-cells are used, wherein the PV-cells are InGaP (680 nm and lower wavelengths), GaAs (680 to 880 nm wavelengths), silicon (880 nm to 1100 nm wavelengths), and Germanium (1100 to 1800 nm wavelengths), the solar spectrum is divided as shown in FIG. 20A. While this spectral separation provides a good match with the high-response portions of the spectral response curves of the PV-cells, it can been from FIG. 20A that the amount of power within each spectral band varies greatly, with the InGaP PV-cell receiving over 46% of the available power and the silicon cell receiving less than 15%. Such disparities can lead to inefficiencies in PV-cell cooling and electrical wiring. An alternate approach is to select PV-cells such that the optical power contained within each of the spectral bands is more equitable, as shown in FIG. 20B. While the power variation among the spectral bands shown in FIG. 20B is less than 1%, a 50% variation is also acceptable, which is still a substantial improvement over the nearly 300% variation of the configuration of FIG. 20A. To achieve equitable spectral power, different PV-cells (having different band-gaps) can be used, or the PV-cells can be made from the same materials described in connection with FIG. 20A but can be tuned by the addition of impurities or other crystalline modifications. In any event, the spectral reflectance ranges of the reflectors of the reflector assembly will need to be adjusted accordingly.

In one embodiment, the concentrated solar converter invention prescribed herein consists of a condensing fresnel lens, a unitary spectral-separating reflector assembly, and a plurality of PV-cells whose conversion characteristics are matched to the distinct wavelength bands output by the reflector assembly, wherein the reflector consists of several reflectors of differing spectral reflectance placed in close proximity to one another and bonded together to form a low-loss small form-factor assembly.

There is set forth herein, in one embodiment, a high-performance solar concentrator that is configured to utilize several single-junction PV-cells per concentrator. The optical system consists of a condensing fresnel lens, a lower reflector assembly that consists of a plurality of reflectors arranged in a cascade configuration and angled with respect to one another, and a plurality of photovoltaic cells of differing bandgaps. Each reflector is reflective to a selected band of wavelengths, and is transmissive to longer wavelengths that are reflected by lower reflectors. Each reflector reflects and directs onto a PV cell that selected band of wavelengths that the PV cell is most responsive to. One or more of the reflectors of the reflector assembly can be planar, microstructured with a fresnel surface, or curved. The reflector assembly can be located on the optical axis of the condensing fresnel lens, or located off of the optical axis.

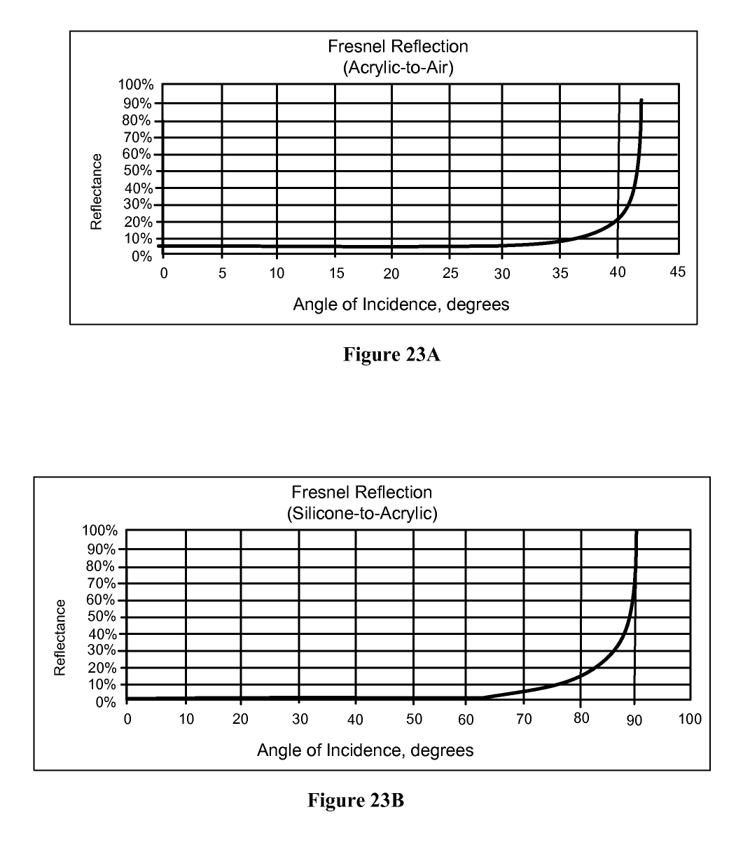

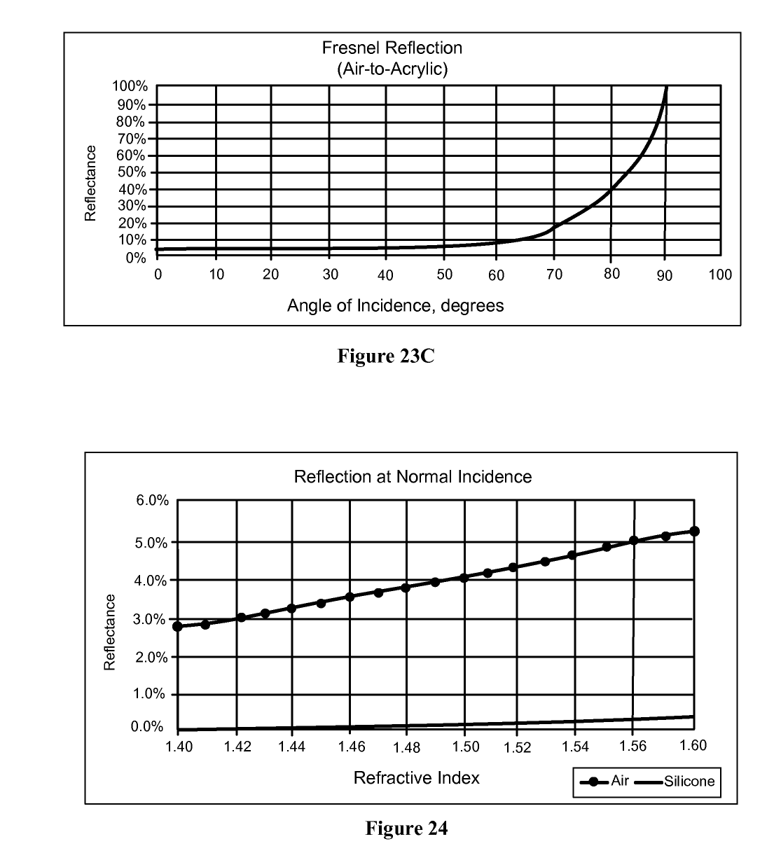

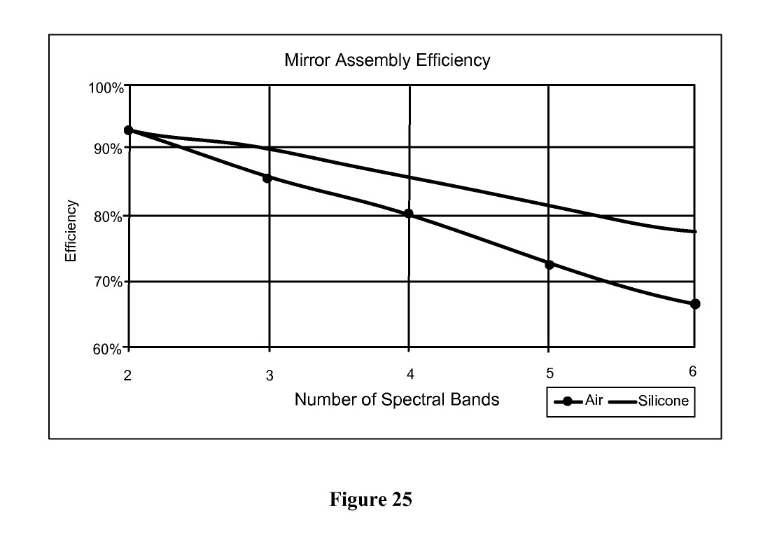

As mentioned earlier, the adhesive bonding the mirror substrates together can have a refractive index similar to the refractive index of one or both of the substrates that are being bonded together. Meeting this condition of similar refractive indices will minimize the fresnel reflectance occurring at the adhesive—substrate interface. Since the light that is reflected in this manner will generally be reflected into a wrong direction and not reach the correct PV-cell, the energy in the light will be wasted resulting in a decrease in system efficiency. FIG. 21 shows the refractive index of silicone as a function of wavelength for the wavelengths range of 350 nm to 1800 nm. Similarly, FIG. 22 shows the refractive index for acrylic over the same range of wavelengths. If air, having a refractive index of substantially 1.00 is placed between the substrates, then at each air-acrylic interface approximately 4% of the light will be lost at angles of incidence of less than 25°, as shown in FIGS. 23A and 23C, although the same effect will be realized with materials other than acrylic, such as polycarbonate or glass. On the other hand, if silicone is placed between the mirror substrates, the stray-light (fresnel) reflectance is less than 1% at angles of incidence out to 60° angles of incidence as shown by FIG. 23B. Clearly, the addition of an index-matching material at the surface of the substrate offers a substantial reduction of stray light and a corresponding improvement in the amount of light reaching the correct PV-cell and an overall performance improvement. However, the refractive index matching does not need to be perfect; as seen from FIGS. 21, 22, 23, and 24, a refractive index difference of up to 0.20 is acceptable, although an index difference of 0.10 is preferred, and an index difference of less than 0.05 is further preferred.

In one embodiment, an adhesive layer and an adjoining substrate having matching refractive indices can be in optical contact with one another. Optical contact means that the two components are physically touching one another, and that a light ray passing from one component (e.g., a substrate) into the second (e.g., the adhesive) does not pass through an intermediate layer of material (e.g., air), regardless of how thick or thin the intermediate layer might be, after it leaves the first but before it enters the second substrate. Two solid objects can be regarded to be in optical contact with one another if the distance between the objects is less than the wavelength of light, but obtaining such an arrangement over several centimeters of substrate surface can be challenging. In general, optical contact is readily obtained if one of the two materials forming an interface is a fluid and the other is a solid.

In the present invention the substrate is the solid material and the fluid is the adhesive. An air-solid interface generally has substantial fresnel reflections of light at the interface (as described in connection with FIGS. 23A and 23C) whereas a liquid-solid interface generally has significantly less fresnel reflection owing to the similarity of the refractive indices of most transparent dielectric solids and liquids. Note that the liquid side of the interface can be of low-viscosity, such as many cyanoacrylate glues and optical adhesives, or it can be highly viscous, such as a pre-cured silicone gel, non-cured silicone, or other adhesives, whose low fresnel reflectances are described in connection with FIG. 23B. Most solid-solid interfaces start out as a solid-liquid interface, wherein the liquid side of the interface flows and conforms to the macro and microscopic contours of the solid surface, and then the liquid side of the interface is caused to harden and solidify, perhaps as part of a curing process, such that it retains its shape at the interface after hardening and precludes the presence of air at the interface.

The refractive index matching between the adhesive layer and the adjoining substrate can be provided in an embodiment wherein two components are in optical contact with one another. By being in optical contact two components can be physically touching one another so that a light ray passing from one component (e.g., a substrate) into the second (e.g., the adhesive) does not pass through an intermediate layer of material (e.g., air) after it leaves the first but before it enters the second.

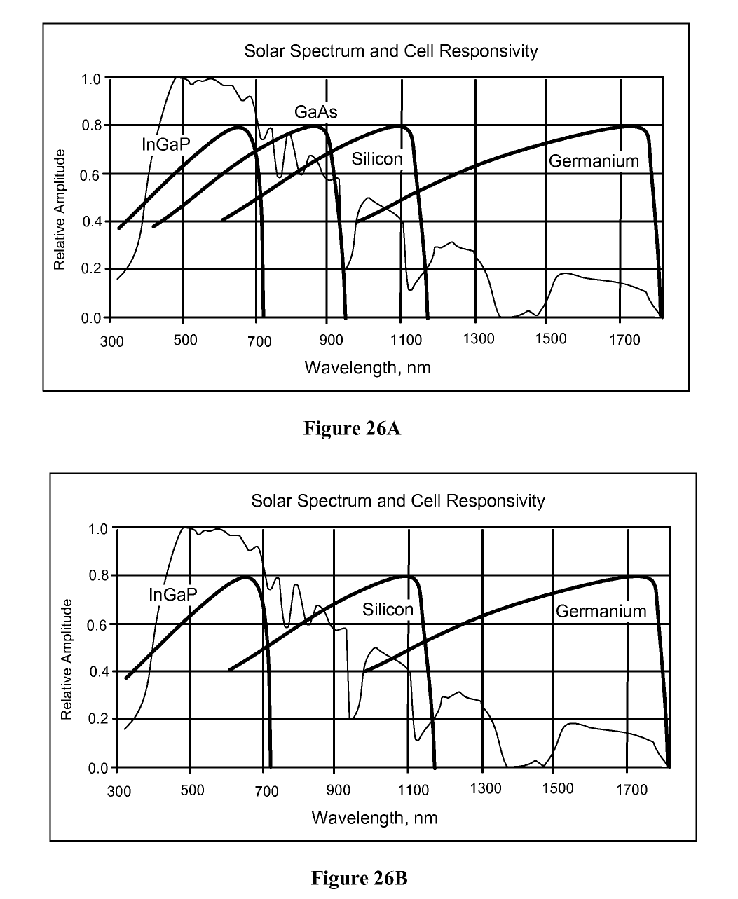

FIG. 24 is a graph of light reflectance (vertical axis) as a function of refractive index (horizontal axis) of the incident medium when air is the second material of the interface and when silicone is the second material of the interface, at a wavelength of 800 nm, at normal incidence. This graph illustrates an alternate way of discerning how large a reduction of fresnel reflection can be made with the addition of silicone (and the removal of air) as the second media. Indeed, even if a high index material such as polycarbonate (n=1.58) is used as the incident medium, the fresnel reflection still results in only 0.5% of light being lost instead of over 5% with air.

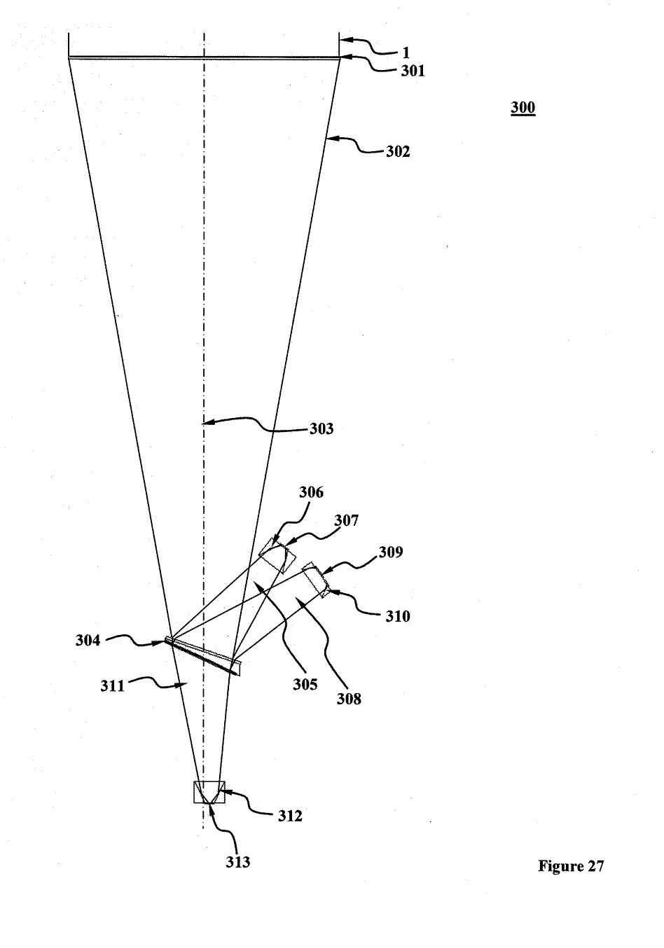

The preceding paragraphs, in connection to FIGS. 23 and 24, assumed a single substrate interface. Since the reflector assembly of most embodiments of the present invention has at least two such interfaces, the effects of using an index-matching material between the substrates (instead of air) can be expected to be even more pronounced. Indeed, FIG. 25 illustrates the mirror assembly efficiency, defined as (total light input to the reflector assembly minus total stray fresnel-reflected light) divided by total light input to the reflector assembly, as a function of the number of spectral bands output by the mirror assembly. For example, if there is a single split (arising from a single mirror) then there are two spectral bands, and the efficiency is 100% minus 4% fresnel reflectance loss at the upper mirror surface minus 4% fresnel reflectance loss at the lower mirror surface. Since there is just one substrate, no adhesive is necessary (i.e., there is no air between any mirrors to be filled with an index-matching adhesive) and both the air and the silicone plots have the same 92% efficiency. Note, this assumes that the out-of-band transmittance of the reflective surface of the mirror is 4%, which is determined substantially by the characteristics of the reflector and less by fresnel-reflectance phenomena.

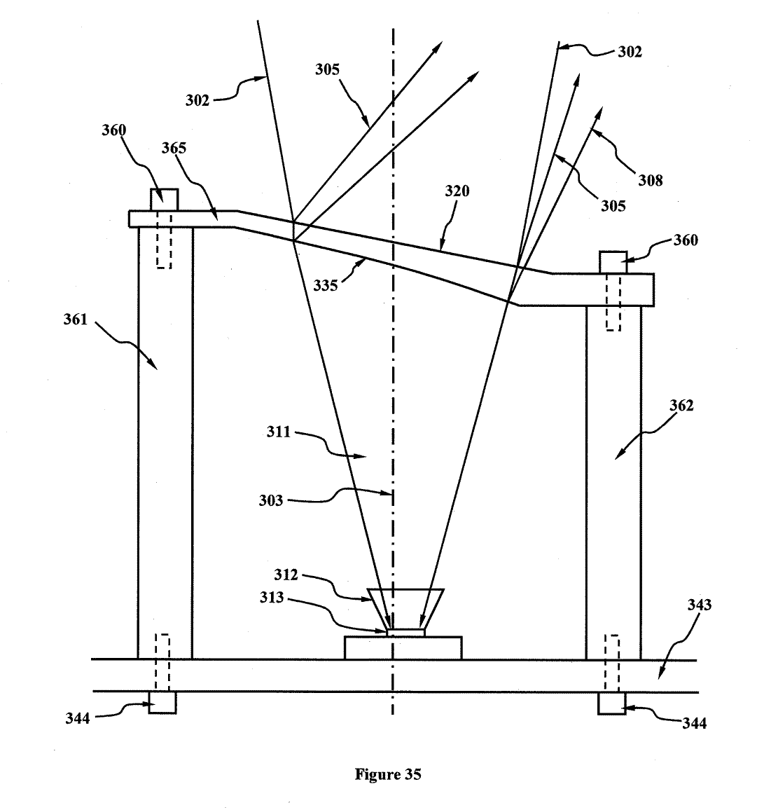

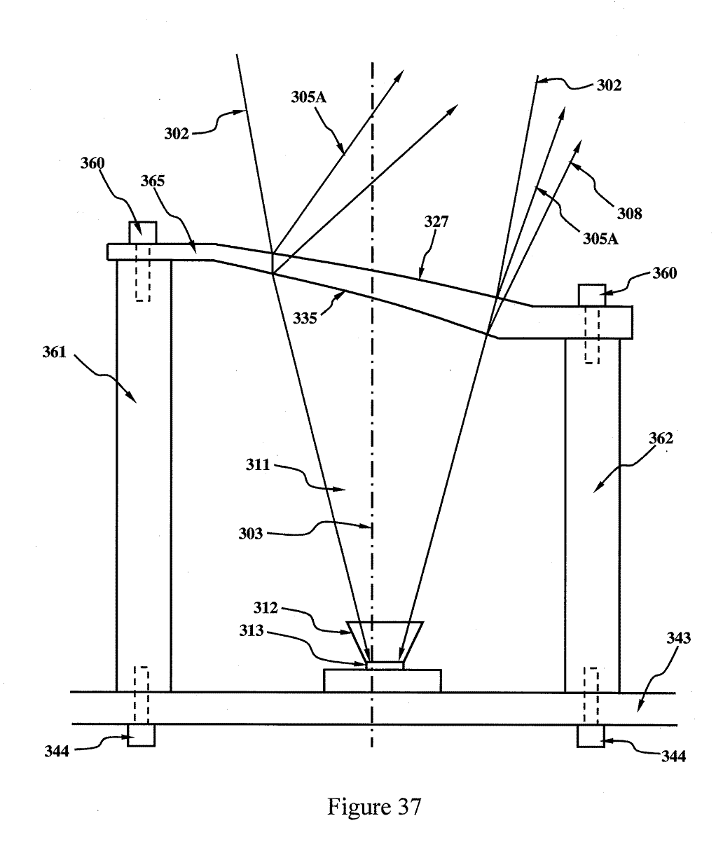

Continuing with FIG. 25, it is seen that as soon as a second reflector is installed (i.e., three spectral bands) then the use of an index matching material installed between the substrates and in optical contact with the substrates substantially improves the efficiency of the reflector assembly. Specifically, the efficiency is 91% if a silicone adhesive is employed, whereas the efficiency drops to 85% if it is not, although other types of adhesives can be used or non-adhering materials such as gels or liquids can be used to perform the index matching function. Note that the present discussion, and FIG. 25, assumes the addition of an index matching adhesive between the two mirror surfaces. An alternate configuration, in which reflective surfaces are installed on each side of a common substrate, has the same 91% efficiency (see, for example, FIG. 35 and FIG. 37), although there may be other factors that make this embodiment less attractive. Note in FIG. 25 that the disparity in mirror assembly efficiency becomes more pronounced with an increasing number of spectral bands and reflectors. The math behind FIG. 25 assumed that the reflective surfaces had 95% reflectance (5% transmittance) to the reflected wavelengths (and the non-reflective surfaces had only fresnel reflectances as described in the preceding paragraphs).

While the photovoltaic conversion process efficiency improves with the number of spectral bands, the reflector assembly efficiency decreases with the number of spectral bands. Judging by the efficiency fall-off of the curves in FIG. 25, the reflector assembly efficiency reduction seen at five spectral bands will offset all performance gains obtained with improved PV-cell conversion, and the overall system performance (as a function of the number of spectral bands) will begin to fall off. Note that this can be improved by improving the quality of the reflective layers. Assuming a reflector reflectivity of 95%, from an overall efficiency performance viewpoint, the optimum number of spectral splits in the example described appears to be three or four.

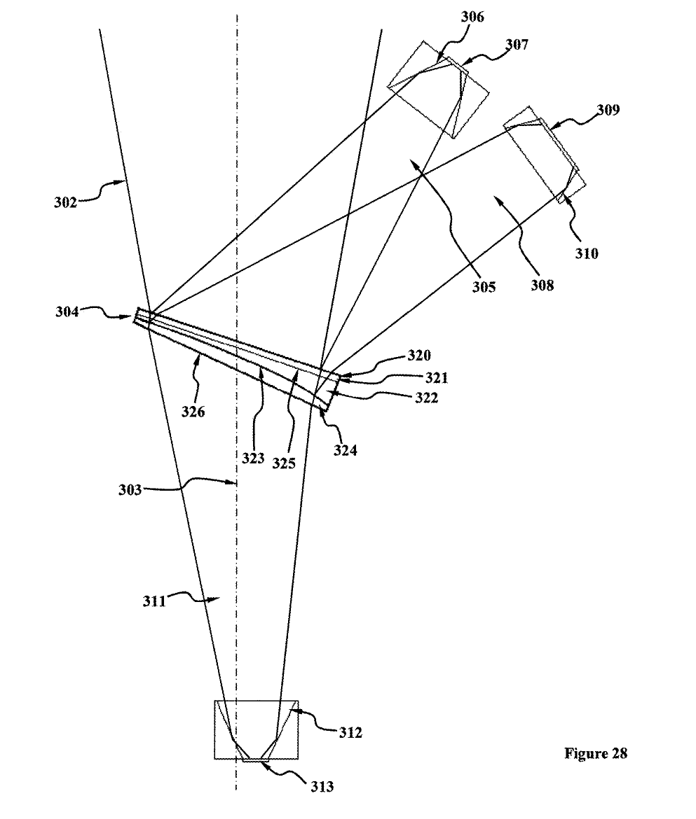

Next in FIG. 26A is shown the solar spectrum insulation curve overlaid with the response curves of four common types of PV-cells that are likely to be used in a four-band system (i.e., InGaP, GaAs, Silicon, and Germanium). Note that the GaAs PV-cell does not cover a very wide spectral band (between 680 nm and 910 nm) and the wavelengths of this spectral band can be readily converted at high efficiency by the neighboring silicon PV-cell, as shown in FIG. 26B. That is, by removing a relatively expensive GaAs PV-cell, system performance will decrease a small amount, but the system cost will be reduced even more (percentage-wise). Therefore, from an economics point of view, a system having three spectral bands in one embodiment can provide advantages (for a mirror reflectivity of 95%, etc.).

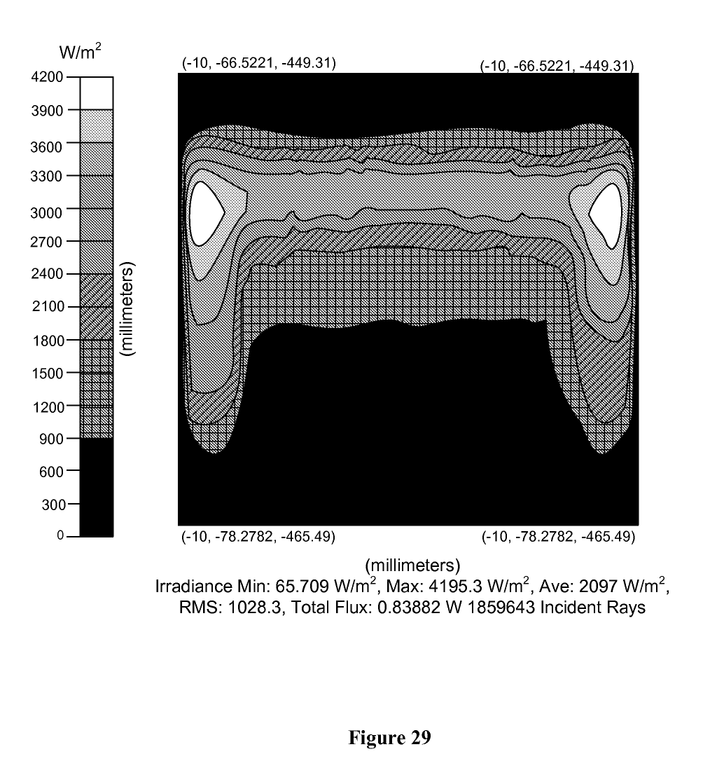

Shown in FIG. 27 is a side-view of an improved spectral-splitting converter 300 having three spectral bands. It is assembled from a fresnel lens concentrator 301 having an optical axis 303, a reflector assembly 304, a PV-cell 313 with secondary optics 312 located near the bottom of the converter 300, a PV-cell 307 with secondary optics 306, and PV-cell 309 with secondary optics 310. PV-cell 307 is shown to have a small active area, and as such PV-cell 307 is a cell that operates with higher efficiency at higher concentrations, such as from 300× to 2000×, such as a cell made from III-V materials such as InGaP. PV-cell 309 is shown to have a larger active area, and as such PV-cell 309 is a cell that operates with higher efficiency at moderate concentrations, such as from 10× to 200×, such as a cell made from silicon. The secondary optics 312, 306, and 310 in one embodiment can be mirrors that redirect any light that overfills the active area of the PV-cells back onto the active area of their respective PV-cells.

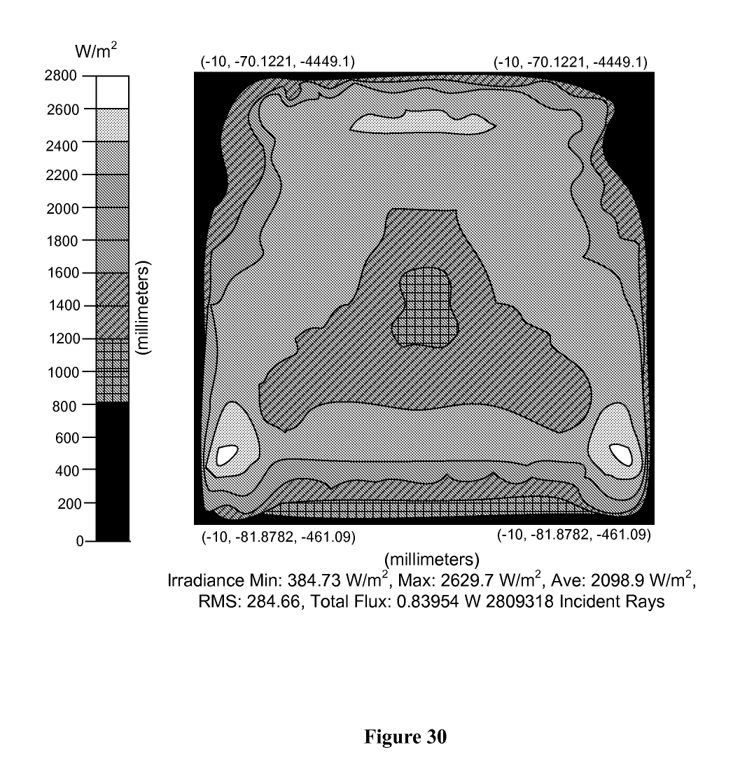

FIG. 28 shows a magnified view of the reflector assembly 304 and PV-cells. In FIG. 28 it is seen that the reflector assembly 304 consists of an upper mirror which is made from a substrate 321 having a reflector 320 defining an upper surface, which can be formed e.g. by a providing of a reflective coating. Both the reflector 320 and the lower surface 325 of the substrate 321 are planar, and the substrate 321 can be preferentially made from glass, although other materials such as polymer can be utilized. A second component of the reflector assembly 304 is the lower mirror which is made from a substrate 324 having a reflector 323 defining an upper surface, which can be formed, e.g. by a providing of a reflective coating. The upper reflector 323 of the substrate in the described embodiment is curved, whereas the lower surface 326 of the substrate is substantially planar. Substrate 324 is nominally made from a moldable polymer material, although other materials such as glass can be used. The lower surface 326 may have an antireflective coating installed onto it, or a subwavelength antireflective microstructure installed into it, to reduce the fresnel reflections occurring at the lower surface 326 interface with the surrounding air. The third component of the reflector assembly 304 is the adhesive layer 322 that bonds or otherwise attaches the upper substrate 321 to the lower substrate 324. Equally important, as described in preceding paragraphs, particularly in connection to FIGS. 21 through 25, the adhesive layer acts as an index-matching material that reduces (or substantially eliminates) the fresnel reflection occurring at the optical interface at the lower surface 325 of the upper substrate and possibly the upper reflector 323 of the lower substrate 324. The adhesive layer 322 can be a UV-curable material, solvent-curable material, or a silicone. Silicones are especially attractive due to their long life-times, low cost, and resistance to UV energy.

Continuing with FIG. 28, the upper PV-cell 307 is sized such that its active area is 8 mm×8 mm, and operates at 625× concentration, although other sizes and concentrations are possible. PV-cell 307 is typically a III-V type of cell such InGaP or InGaN, although other materials choices can be made for this cell. Larger PV-cell 309 on the other hand includes an active area having a surface area of 20 mm×20 mm, and operates at 100× concentration, although other sizes and concentrations are possible. Typically, the larger PV-cell 309 is made from silicon. In the development of the described system it was noted that silicon PV-cells operate more efficiently at lower concentrations than III-V PV-cells. Such 100× silicon PV-cells are manufactured by Narec of Northumberland in the UK.

In the development of the described system it was determined that advantages can be provided by providing a first PV-cell of a first material to include an active surface having a surface area larger than a surface area of an active area of a second PV-cell of a second material. In the development of the described system it was determined that such configuration provides improved efficiency given that some certain PV-cells provide greater performance with reduced light concentration. A certain configuration of a light collection unit can be repeated throughout an array as is set forth herein.

Accordingly, there is set forth herein an apparatus for converting solar energy, the apparatus comprising an optical element for converging solar radiation; a reflector assembly receiving light transmitted by the optical element and including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, the second reflector being adapted to transmit one or more other spectral band of light outside of the second spectral band of light, wherein the apparatus for converting solar energy is configured so that a reflector of the first and second reflector transmits light reflected from the remaining of the first and second reflector; wherein the apparatus for converting solar energy further includes a first photovoltaic cell and a second photovoltaic cell, the first photovoltaic cell being disposed to receive light reflected from the first reflector and being particularly responsive to the first spectral band of light, the first photovoltaic cell having a first active area, the second photovoltaic cell disposed to receive light reflected from the second reflector and being particularly responsive to the second spectral band of light, the second photovoltaic cell having a second active area, the second active area having a surface area that is at least 1.5 times the surface area of the first active area, wherein first active area is defined by a first type of material and wherein the second active area is defined by a second type of material.

There is also accordingly set forth herein an apparatus comprising an array of converters, wherein first, second, and third converters of the array comprise an optical element for converging solar radiation, a first reflector and a second reflector, the first reflector of the first, second, and third converter adapted to reflect a first spectral band of light transmitted by its respective optical element, the first reflector being adapted to transmit one or more other spectral band of light outside of the first spectral band of light, the second reflector of the first, second, and third converter being adapted to reflect a second spectral band of light transmitted by its respective optical element, the second reflector of the first, second, and third converter being adapted to transmit one or more other spectral band of light outside of the second spectral band of light, wherein the first, second, and third converter further include a first photovoltaic cell and a second photovoltaic cell, the first photovoltaic cell of the first, second, and third converter being disposed to receive light reflected from its respective first reflector and being particularly responsive to the first spectral band of light, the second photovoltaic cell of the first, second, and third converter being disposed to receive light reflected from its respective second reflector and being particularly responsive to the second spectral band of light, the second photovoltaic cell of the first, second, and third converter having an active area surface area that is at least 1.5 times an active area surface area of its respective first photovoltaic cell, wherein the active area of the first photovoltaic cell of the first, second, and third converters is defined by a first type of material and wherein the active area of the second photovoltaic cell of the first, second, and third converter is defined by a second type of material.

According to one embodiment a second PV-cell can have an active area surface area of at least 1.5 times the surface area of an active area of a first PV-cell. According to one embodiment, a second PV-cell can have an active area surface area of at least 2 times a surface area of an active area of a first PV-cell. According to one embodiment, a second PV-cell can have an active area surface area of at least 3 times a surface area of an active area of a first PV-cell. According to one embodiment, a second PV-cell can have an active area surface area of at least 4 times a surface area of an active area of a first PV-cell.

Owing to the geometry of the optical system, and the relative sizes and placements of PV-cells 307 and 309 and their associated secondary optics 306 and 310, the secondary optic 310 associated with the larger PV-cell 309 has a small impact on light uniformity on the active area of the PV-cell 309, whereas the secondary optic 306 associated with the smaller PV-cell 307 where appropriately engineered can have significant impact on the uniformity of the light incident on the smaller PV-cell 307. Indeed, the prescription of secondary optic 306 can be readily engineered to optimize the uniformity of the light reaching PV-cell 307, which is not true of secondary optic 310 for light reaching the larger PV-cell 309. In the development of the described system it was determined that an alternative optical element can be engineered to improve the uniformity of the light incident on larger PV-cell 309. This surface will be identified and described in the forthcoming paragraphs.

In operation, sunlight 1 is incident on the concentrating fresnel lens 301 which causes the sunlight to converge along convergence cone 302 on optical axis 303. The converging sunlight 302 is then incident on reflector 320 of substrate 321 of reflector assembly 304, which is made reflective to a band of wavelengths that PV-cell 307 is particularly responsive to. This band of wavelengths reflects from the reflector 320 in a converging bundle of light 305 that is directed to PV-cell 307 and its associated reflective secondary optic 306. Together, the prescription of the secondary optic 306 and its positioning, as well as the size and positioning of the PV-cell 307 combine to capture substantially all of the light contained in converging light bundle 305 in a way that the concentration of the light incident on PV-cell 307 is optimized, and the light incident on PV-cell 307 is highly uniform.

Converging light that is not reflected by reflector 320 refracts into the substrate 321, passes through the lower surface 325 of the substrate, and enters into the adhesive layer 322. It is desirable that the refractive index of the adhesive 322 is similar to the refractive index of the substrate 321 so that stray light caused by fresnel reflections at the interface are minimized as described earlier. Adhesive layer 322 can be non-absorptive to the wavelengths of light passing through it, and non-scattering to them as well. Special silicone adhesives, such as model LS-6941 made by NuSil of Carpinteria, Calif., USA, meet these requirements.

Adhesives (also known as glues) which can be utilized to provide adhesive layers set forth herein, and which can be disposed between first and second substrates as set forth herein come in two primary forms: reactive and non-reactive. Non-reactive adhesives include pressure-sensitive adhesives (PSA) which form a bond between the adhesive and the adhered by the application of pressure; contact adhesives (such as natural rubber and neoprene) which form a bond between two contact-adhesive-coated surfaces when they simply come into contact with one another; hot adhesives or hot-melt adhesives which are simply thermoplastics that are applied in molten form and solidify to form a strong bond; and drying adhesives which are solvent based and contain a mixture of ingredients (such as polymers) dispersed in a solvent—as the solvent evaporates the adhesive hardens. Reactive adhesives include multi-part adhesives such as acrylics, urethanes, and epoxies, in which the adhesive hardens when two or more components are mixed together and chemically react. On the other hand a one-part adhesive hardens via a chemical reaction with an external energy source, such as radiation, heat, or moisture. Ultraviolet (UV) light-curing adhesives can harden quickly when exposed to UV light, are generally formulated with acrylic compounds, can adhere to a variety of materials, including those used in the field of optics. Heat-curing adhesives consist of a mixture of two or more components, and when exposed to heat the components react together and cross-link Moisture-curing adhesives include cyanoacrylates, and cure when they react with moisture present on or within the surfaces being bonded together.

Adhesion provided by adhesive layers as set forth herein may occur by mechanical means, in which the adhesive works its way into small pores, or into or around microscopic and macroscopic features of the substrate, or by one of several chemical mechanisms in which the adhesive forms a chemical bond with the substrate. A third adhesive mechanism involves the use of van der Walls forces at the molecular level. A fourth adhesive mechanism involves the diffusion of the adhesive into the substrate followed by hardening.

Silicone adhesives can be either one-part or two-part. One-part silicones contain all the ingredients needed to produce a cured material. They use external factors—such as moisture in the air, heat, or the presence of ultraviolet light—to initiate, speed, or complete the curing process. These one-part systems are commonly referred to as RTV's, meaning Room Temperature Vulcanizing. This type of silicone chemistry is the most widely used in the formulation of adhesive silicones that utilize moisture in the atmosphere to react with chemical cross linkers, thereby enabling the formation of a silicone elastomer. They are normally described in terms of the small amount of the chemical by-product produced during the reaction. The most common systems are acetone, acetoxy, oxime, and alkoxy or methoxy. Two-part systems segregate the reactive ingredients to prevent premature initiation of the cure process. They often use the addition of heat to facilitate or speed cure.

Any of the adhesives described in the preceding paragraphs may be suitable as the material that bond two or more substrates together, although other types of adhesives not explicitly described may be utilized instead.

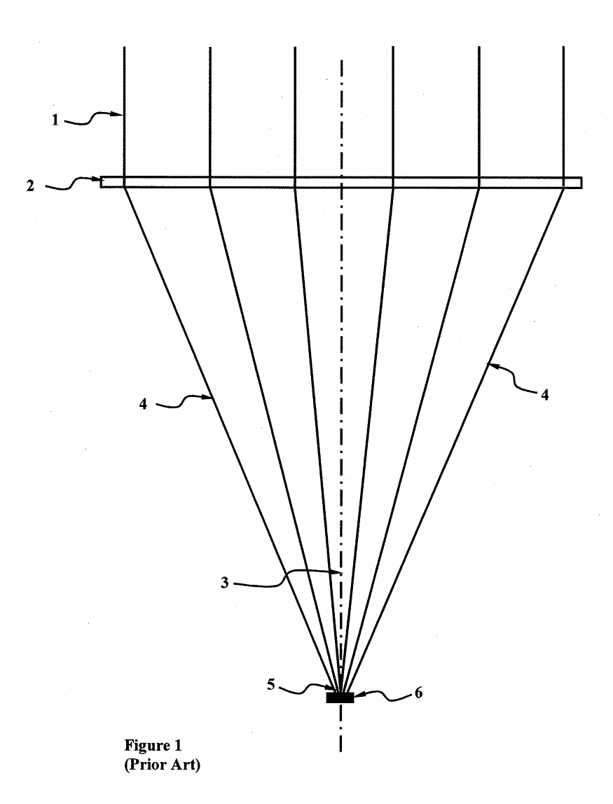

As has been indicated in respect to the teachings of FIGS. 1-19, there is set forth herein an apparatus for converting solar energy, the apparatus comprising an optical element for converging solar radiation; and a reflector assembly receiving light transmitted by the optical element and including a first substrate having a first reflector and a second substrate spaced apart from the first substrate and having a second reflector, the first reflector being adapted to reflect a first spectral band of light transmitted by the optical element, the first reflector being adapted to transmit one or more spectral band of light outside of the first spectral band of light, the second reflector being adapted to reflect a second spectral band of light transmitted by the optical element, the second reflector being adapted to transmit one or more spectral band of light outside of the second spectral band, wherein the reflector assembly is configured so that a reflector of the first and second reflector transmits light reflected from the remaining of the first and second reflector, wherein the reflector assembly further includes a layer of material disposed between the first substrate and the second substrate, the layer of material being in contact with the first substrate and the second substrate, wherein the layer of material has an index of refraction matched to an index of refraction of the first substrate; and wherein the apparatus for converting solar energy further comprises a first photovoltaic cell and a second photovoltaic cell, wherein the first photovoltaic cell is disposed to receive light reflected from the first reflector, wherein the second photovoltaic cell is disposed to receive light reflected from the second reflector, wherein the first photovoltaic cell is particularly responsive to the first spectral band of light, and wherein the second photovoltaic cell is particularly responsive to the second spectral band of light.

There is accordingly also set forth herein the described apparatus for obtaining energy wherein the layer of material is capable of curing. There is also set forth herein the described apparatus for obtaining energy wherein for providing the apparatus, the layer of material is disposed between the first and second substrate in an uncured state and is subsequently cured. There is also set forth herein the described apparatus for obtaining energy wherein the layer of material provided by a material that is capable of hardening responsively to one of applied radiation, heat, and pressure. There is also set forth herein the described apparatus for obtaining energy wherein the layer of material is adapted to conform to a shape of the first and second substrate responsively to applied energy. There is also set forth herein the described apparatus for obtaining energy wherein the layer of material is in optical contact with the first substrate and second substrate and wherein for providing the apparatus, the layer of material is disposed in a first state and hardens to conform to a shape of the first and second substrate.

With further reference to FIG. 28, after the converging light propagates through the adhesive layer 322 it is then incident upon the reflector 323 of the lower substrate 324. In previous descriptions of previous embodiments of the present invention, reflector 323 has been described as being planar in shape. A planar-shaped surface can be preferable because it is generally of low-cost, and should be used as the shape-of-choice for the reflective surfaces of the spectral splitting assembly 304. However, a planar-shaped reflector cannot always provide for uniform illumination of light on the active area of the receiver that the light from the reflector is directed onto. Nonetheless, if the active area of the receiver is small, such as the case for PV-cell 307 and its secondary optic 306, then the light reflected from the planar reflector 320 can be made to overfill the PV-cell 307 as long as substantially all of the overfilling light 305 is incident on the secondary optic 306 which can then reflect the overfilling light onto the active area of the PV-cell 307. In this case the angle of the reflective surfaces within the secondary optic 306, and/or its prescription, can be engineered in such a way to cause the illumination on the PV-cell 307 to be highly uniform. Note for this to be effective the depth of the secondary optical element 306 should be at least twice as great as a width of the PV-cell 307.

Turning our attention for the moment to the larger PV-cell 309 of FIG. 28, it is seen that the large PV-cell 309 is also being overfilled with light, and that this overfilling light is being reflected by secondary optical element 310 onto the PV-cell 309. However, note that secondary optical element 310 can be provided to be relatively shallow, because if made relatively deep, such as at least twice as deep as a width of its accompanying PV-cell 309, the secondary optical element 310 would protrude deep into the converter and block some of the light being directed onto the other PV-cell 307 (or its secondary optic 306). In the development of the described system, it was determined that since the secondary optic 310 cannot be made deep enough to satisfactorily improve the uniformity of the light incident on the larger PV-cell 309, an alternate method, or surface, can be utilized to effect an improvement in illumination uniformity on the larger PV-cell 309. In one embodiment, secondary optical element 310 can be relegated to the role of capturing any stray light, or redirecting onto the PV-cell 309 light that misses PV-cell 309 due, for example, to array tracking or pointing errors, or opto-mechanical tolerances within the converter.

There are a limited number of surfaces available within the reflector assembly 304 that can be used to facilitate an improvement in illumination uniformity on PV-cell 309. Reflector 320 can be kept planar to minimize costs, and in actuality making reflector 320 non-planar can degrade the uniformity of the light incident on PV-cell 307. The lower surface of the upper substrate 321 can be in optical contact with material 322, which can have an index of refraction matched to the index of refraction of the upper substrate 321, and can therefore provide little or no opportunity for light manipulation through refraction at the interface. Instead, reflector 323 of lower substrate 324 can offer an opportunity for controlling the light reaching PV-cell 309. Indeed, in the development of the described system it was determined that reflector 323 of the lower substrate 324 can be modified to be non-planar to improve the uniformity of the light incident on the larger PV-cell 309, in such a manner that does not impact the uniformity of the light incident on the other PV-cells of the system.

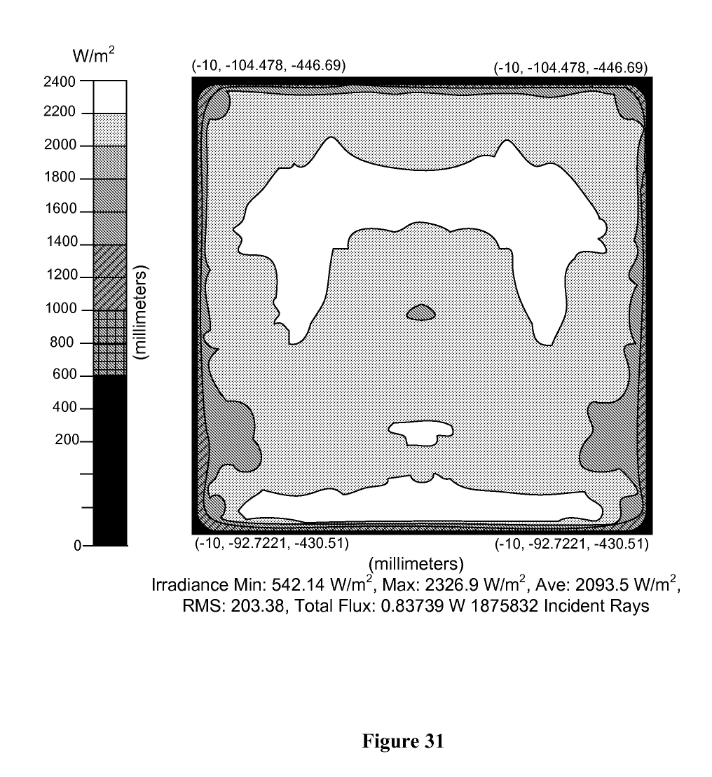

For example, FIG. 29 is an irradiance plot of the illumination on PV-cell 309 in which PV-cell 309's active area has a surface area of 20 mm×20 mm in size and reflector 323 is planar. The black areas of the plot of FIG. 29 indicate areas of little of no illumination, while the white areas indicate regions of excessively high illumination. Indeed, the maximum minus minimum irradiance is 4195 W/m²−66 W/m₂=4129 W/m². This described level of illumination uniformity will prevent PV-cell 309 from operating efficiently in its photon to electron conversion process. In the development of the described system it was determined that making reflector 323 of lower substrate 324 non-planar such that the uniformity of the illumination of PV-cell 309 is improved can improve the conversion efficiency of the PV-cell 309.

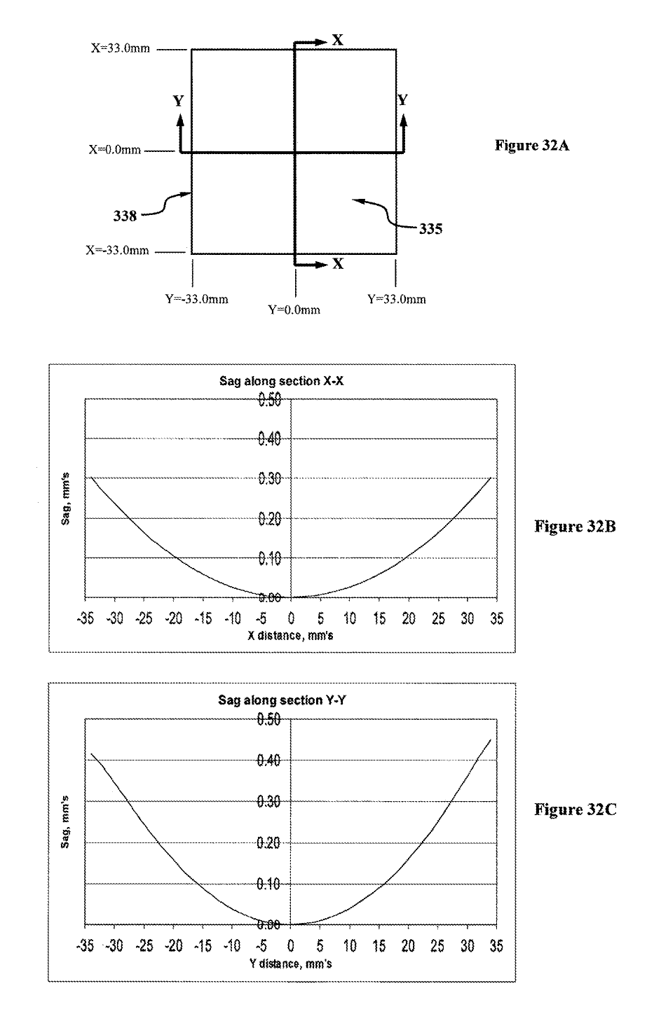

The reflector 323 can be made to be non-planar or otherwise curved in one axis (e.g., left to right) or in two axis (e.g., left to right and into and out-of the paper) of FIG. 28. If the curvature of reflector 323 is in only the left-to-right axis (i.e., the Y axis), then the uniformity of the illumination on the larger PV-cell 309 can be markedly improved as shown in the irradiance plot of FIG. 30. The optical prescription, or equation describing the sag of the reflector 323 is:

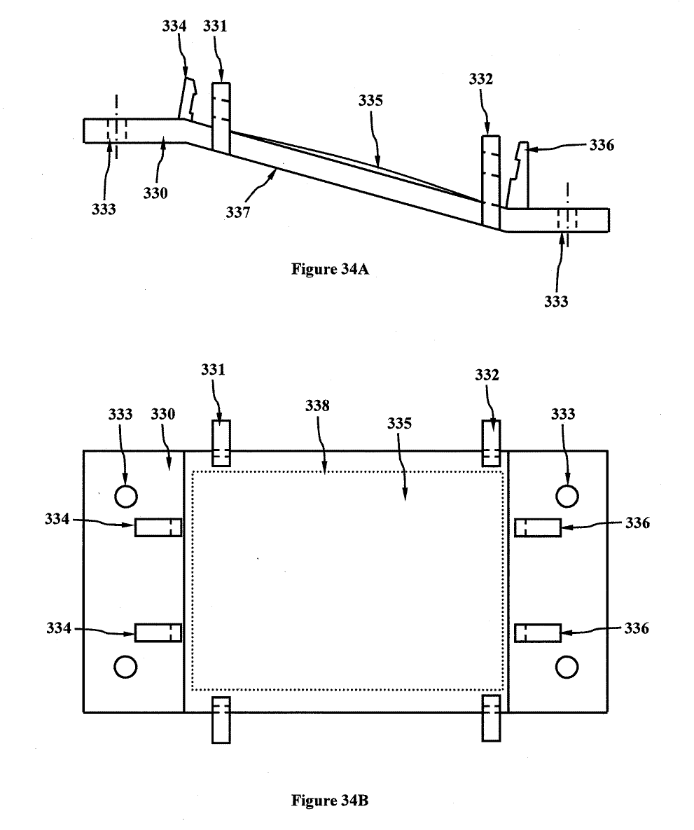

Sag=2.0828×10⁻⁴Y²+8.3286×10⁻⁸Y³+3.305×10⁻⁸Y⁴−2.2375×10⁻⁹Y⁵−5.5337×10⁻¹¹Y⁶−6.03587×10⁻¹⁴Y⁷−4.6404×10⁻¹⁴Y⁸+2.1728×10⁻¹⁵Y⁹+9.7161×10⁻¹⁷Y¹⁰ (Equation 1)

where the Sag and Y are in millimeters. Note that this is a 10^{th} order polynomial as a function of Y, although lower order polynomials, such as 2^{nd} order, can suffice, as well as surfaces described by other forms of non-polynomial mathematical expressions. Sag is defined as the droop or reduction in elevation of an optical surface, relative to its highest point. The curves represented in FIG. 32B and FIG. 32C represent positive sag, and are consistent with the positive sag illustrated by reflector 323 in FIG. 28.

FIG. 30 is a plot of the irradiance incident on the active area of the larger PV-cell 309 when the lower reflector of the reflector 323 has the prescription of Equation 1. Note that the difference between the maximum irradiance and the minimum irradiance has been reduced to 2630 W/m²−385 W/m²=2245 W/m² and one can also qualitatively see that the uniformity has been significantly improved when compared to the irradiance plot of FIG. 29.

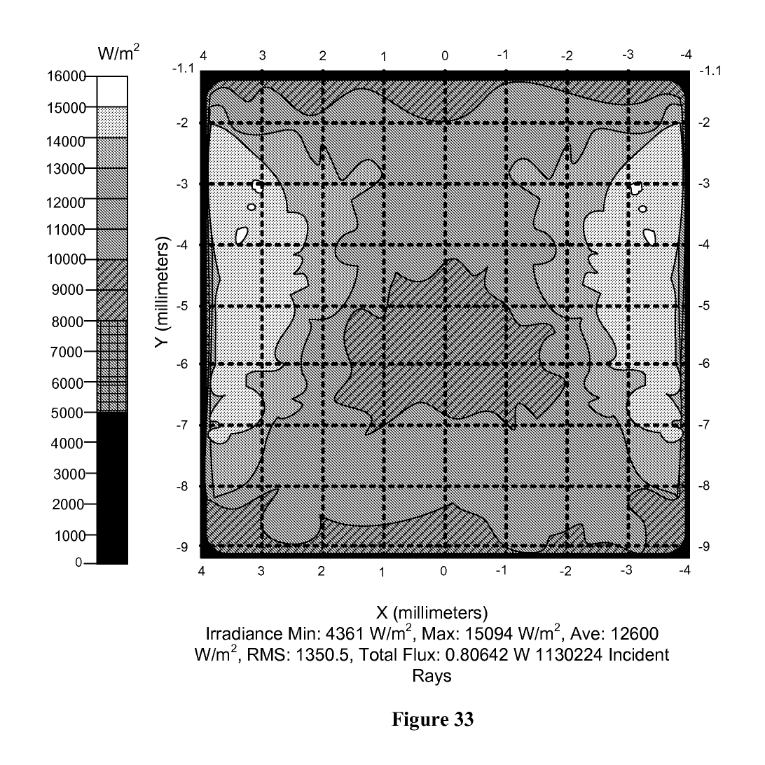

If the curvature of reflector 323 is in both the left-to-right axis (i.e., the Y axis) as well as the axis into and out-of the plane of the paper (i.e., the X-axis) then the uniformity of the illumination on the larger PV-cell 309 can be improved further as shown in the irradiance plot of FIG. 31. Continuing with the example of a 20 mm×20 mm size of a larger PV-cell 309 (an active area of PC-cell 309 has a surface area of 20 mm×20 mm), the optical prescription, or equation describing the 2-dimensional sag of the reflector 323 is:

Sag=2.6181×10⁻⁴X²+3.976×10⁻⁴Y²+1.818×10⁻⁷Y³+1.5864×10⁻⁸Y⁴−1.476×10⁻¹⁰Y⁵−9.96×10⁻¹¹Y⁶−2.50524×10⁻¹³Y⁷−1.761×10⁻¹³Y⁸+4.7346×10⁻¹⁵Y⁹−1.00824×10⁻¹⁷Y¹⁰ (Equation 2)

where Sag, X, and Y are all in millimeters. Note that this is a 10^{th} order polynomial as a function of Y and second order in X, although lower order polynomials, such as 2^{nd} order, can suffice, as well as surfaces described by other forms of non-polynomial mathematical expressions. FIG. 31 is a plot of the irradiance incident on the active area of the larger PV-cell 309 when the lower reflector of the reflector 323 has the prescription of Equation 2. Note that the difference between the maximum irradiance and the minimum irradiance has been reduced to 2327 W/m²−542 W/m²=1785 W/m², and one can also qualitatively see that the uniformity has been significantly improved when compared to the irradiance shown in plots of FIG. 29 and FIG. 30. Furthermore, in FIG. 31 the areas of low irradiance are small and localized at the edges and corners of the irradiance plot, and are artifacts of the graphing utility of TracePro which was used to create the irradiance plots. As such the maximum minus minimum irradiance seen at the active area of the larger PV-cell 309, when reflector 323 is curved in two axis is likely to be much better than 1785 W/m².

Referring for the moment to FIG. 32A, a plan view of the area 335 of the reflector 323 of the lower substrate 324 is illustrated. In this example the perimeter 338 is shown to be 66 mm×66 mm in size, although other sizes and shapes can work as well. Graphs of the sag in the X-axis and Y-axis are shown in FIG. 32B and FIG. 32C respectively. Note that the shapes in each axis are somewhat parabolic with a sag on the order of half a millimeter. While the surface is roughly parabolic in these two cross-sections, the sag of the reflector 323 is not rotationally symmetric, as evident by the coefficient on the X² term being different than the coefficient on the Y² term. Indeed, if reflector 323 had rotational symmetry, the rotational symmetry would result in a prescription having optical power (as described in earlier embodiments as a means to manipulating the longitudinal placement of the PV-cells for common mounting purposes) as opposed to the intent of the present embodiment of obtaining good illumination uniformity. Nonetheless, a surface having rotational symmetry can be relatively inexpensive to fabricate, and may be able to provide reasonable uniformity at an acceptably low price. Therefore, reflector 323 can be rotational symmetric, such as spherical, or circular, parabolic, or otherwise described by a polynomial in cross-section.

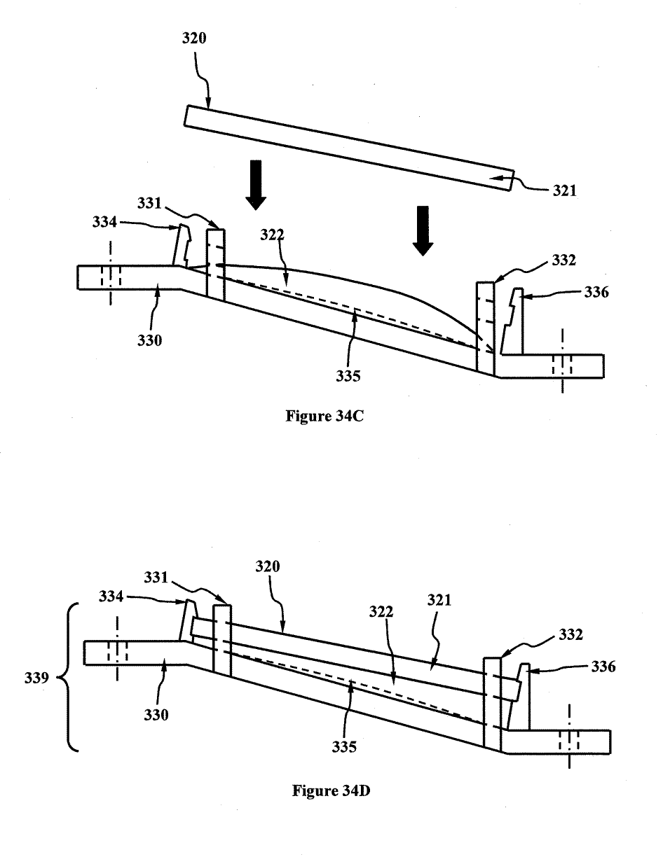

Having thus described an embodiment wherein a reflector 323 of the lower substrate 324 is non-planar, there is set forth relative to FIG. 27 and FIG. 28 a remaining description of the operation of the converter 300. Light that is not reflected by reflector 320 of upper substrate 321 and reflector 323 of lower substrate 324 passes into the lower substrate 324 and exits by refracting through the lower surface 326 of the lower substrate 324. Lower surface 326 is shown to be planar, and the exiting light bundle 311 is incident on lower PV-cell 313 through secondary optical element 312. In the continuing example, lower PV-cell 313 also includes an active area having a surface area of 8 mm×8 mm, and its irradiance uniformity can be modified and improved significantly by engineering the prescription of the reflective surfaces of the secondary optical element 312. The result is the irradiance plot shown in FIG. 33, which is the irradiance of the light incident on the active area of the lower PV-cell 313. Note that while the uniformity on the lower PV-cell 313 is acceptable, it can be improved by changing the shape of the lower surface 326 of lower substrate 324 to a configuration that is non-planar. In this way, the extra degree of design freedom allows the uniformity of the light incident on the lower PV-cell 313 to be optimized. In the particularly described example reflector 323 of lower substrate 324 is non-planar and reflector 320 of upper substrate 321 is planar. However, in another embodiment, the ordering of the non-planar and planar reflectors can be reversed as well as the ordering of PV-cell 309 and PV-cell 313. In another embodiment both reflector 323 and reflector 320 can be non-planar. In any converter embodiment herein having an upper and lower substrate, either the upper or lower substrate can be regarded as a first substrate and the remaining substrate (upper or lower) a second substrate. In any converter embodiment herein having an upper and lower reflector either the upper or lower reflector can be regarded as a first reflector and a remaining reflector a second reflector.

Accordingly, there is set forth herein an apparatus for converting solar energy, the apparatus comprising an optical element for converging solar radiation; a reflector assembly receiving light transmitted by the optical element and including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, said second reflector being adapted to transmit one or more other spectral band of light outside of the second spectral band of light, wherein the apparatus for converting solar energy is configured so that a reflector of the first and second reflector transmits light reflected from the remaining of the first and second reflector; wherein the apparatus for converting solar energy further includes a first photovoltaic cell and a second photovoltaic cell, the first photovoltaic cell being disposed to receive light reflected from the first reflector and being particularly responsive to the first spectral band of light, the first photovoltaic cell having a first active area, the second photovoltaic cell being disposed to receive light reflected from the second reflector and being particularly responsive to the second spectral band of light, the second photovoltaic cell having a second active area, the second active area having a surface area larger than a surface area of the first active area, wherein the second reflector is non-planar and includes a prescription adapting the apparatus so that light reflected by the second reflector is incident on the second active area in a distribution pattern that is more uniform than would be incident on the second active area in the case the second reflector were planar.

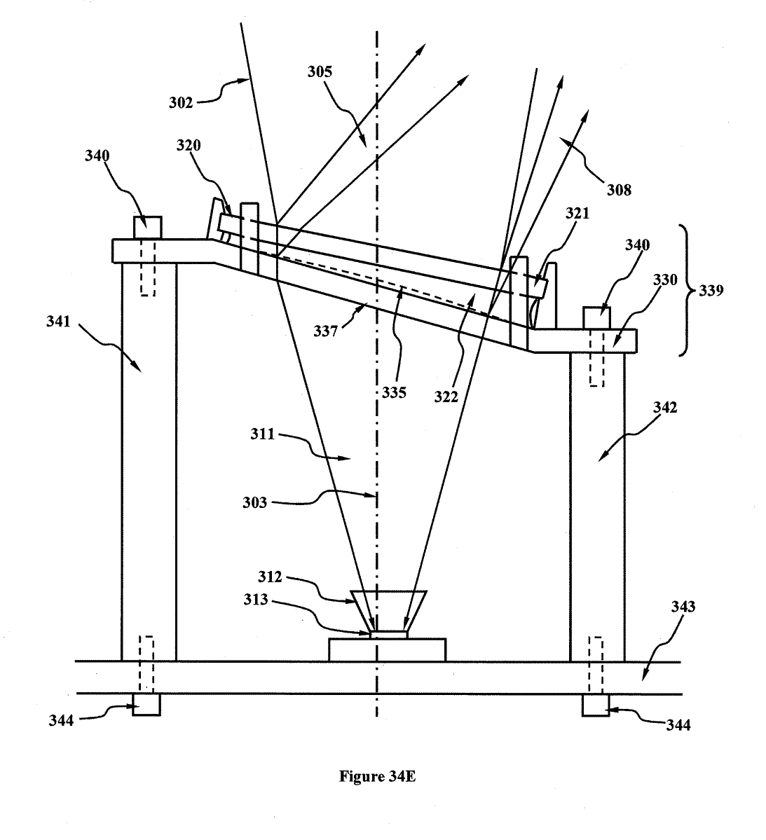

FIG. 34A illustrates a side-view of an embodiment of the lower substrate 324 referenced as element 330 in FIG. 34A. This lower mirror substrate 330 is a molded part with integral features for mounting and alignment, and for attaching an upper substrate 321. Specifically, lower mirror substrate 330 has a curved upper surface 335 molded into it onto which is installed a reflector as described in previous paragraphs for obtaining good illumination uniformity on a moderately sized PV-cell. Furthermore, lower mirror substrate 330 has snap clips 331, 332, 334, and 336 integrally molded into it which are used to capture and retain an upper substrate 321 securely and with good alignment, although other types and numbers of mounts can be provided. Lower mirror substrate 330 also has outlying thru-holes 333 which can be used for attaching lower mirror substrate 330 securely and with good alignment within a converter 300. Lower mirror substrate 330 also has a lower surface 337 which is shown to be planar but can be non-planar in shape to facilitate good uniformity of the light incident on the lower PV-cell 313 as described previously.

FIG. 34B is a plan view of the lower mirror substrate 330. Evident in this view are the integrally molded snap clips 331, 332, 334, and 336 for capturing and retaining an upper substrate 321 securely and with good alignment. Also seen are the outlying thru-holes 333 which are used for mounting the lower mirror substrate 330 and the reflector assembly 304 securely and with good alignment within the converter. Also shown is an outline denoting the perimeter 338 of reflector 335 defining a curved upper surface.

FIG. 34C shows how the upper substrate 321 can be attached to the lower minor substrate 330. During the attachment process a layer of adhesive 322, such as silicone adhesive, is placed atop the reflector 335. Next the upper substrate 321 is positioned above the integrally molded snap clips 331, 332, 334, and 336 of the lower mirror 330, and lowered until it engages and is captured by the molded snap clips 331, 332, 334, and 336.

FIG. 34D shows the completed reflector assembly 339 after the upper substrate 321 has been installed onto the lower minor 330 as described in the preceding paragraph. Note that the upper substrate 321 is securely captured by the integrally molded snap clips 331, 332,334, and 336 of the lower minor 330, and that the adhesive layer 322 has spread out and substantially covers all of the reflector 335. After the adhesive layer 322 cures the upper substrate 321 is firmly secured to the lower mirror substrate 330 with good alignment.

FIG. 34E shows how the completed reflector assembly 339 is positioned and installed within the converter 300. Bolts 340 are placed through the thru-holes 333 of the lower minor 330 into standoffs 341 and 342, which in turn are mounted to the base plate 343 with bolts 344. Standoffs 341 and 342 are of the proper length to provide the correct elevation of the reflector assembly 339 above the base plate 343, as well as the correct spacing between the reflector assembly 339 and the lower PV-cell 313 which is advantageous for good illumination uniformity on the active area of the lower PV-cell 313. The lateral spacing of the various elements (e.g., snap clips, lower surface 337, thru-holes 333, etc.) of the reflector assembly ensures that the lower converging bundle of light 311 is well aligned with the lower PV-cell 313 and its accompanying secondary optical element 312. Illustrative incident rays 302, reflected ray bands 305 and 308, and transmitted rays 311 are shown as well, and operate in accordance with that described previously.

Note that the three-band spectral splitter described in connection with FIGS. 27 through 34 has two separate reflectors 320, 335 on two separate substrates 321 and 324 (or 321 and 330). Combining these two parts into one substrate having a reflector 320 and reflector 335 defining a curved lower surface would eliminate the expense of an additional adhesive layer 322 and the expense of having two separate parts that need to be attached together as described in connection with FIGS. 34C and 34D. Furthermore, such an arrangement precludes the possibility of fresnel reflections occurring at the adhesive/substrate interface due to a refractive index mismatch, and therefore offers a more robust method of improving the efficiency of the spectral splitter.

FIG. 35 illustrates a three-band spectral splitter in which the two spectral-splitting reflectors are installed onto a single substrate 365. Upper reflector 320 is normally a low-cost planar surface whereas the lower curved surface 335 is curved as described previously to offer the benefit of good illumination uniformity on the active area of the large area PV-cell 309. The single substrate 365 also has outlying thru-holes 333 through which bolts 360 attach the single substrate 365 to standoffs 361 and 362 securely and with good alignment. As in previous embodiment the standoffs 361 and 362 position the spectral splitter at the proper elevation and position above the lower PV-cell 313 and its accompanying secondary optical element 312. While this embodiment offers considerable cost benefits compared to previously described embodiment, it does not offer a provision for improving the uniformity of the illumination on the active area of the lower PV-cell 313, nor is it expandable to splitting the incident converging light 302 into four or more spectral bands. These limitations are remedied in the following embodiment.

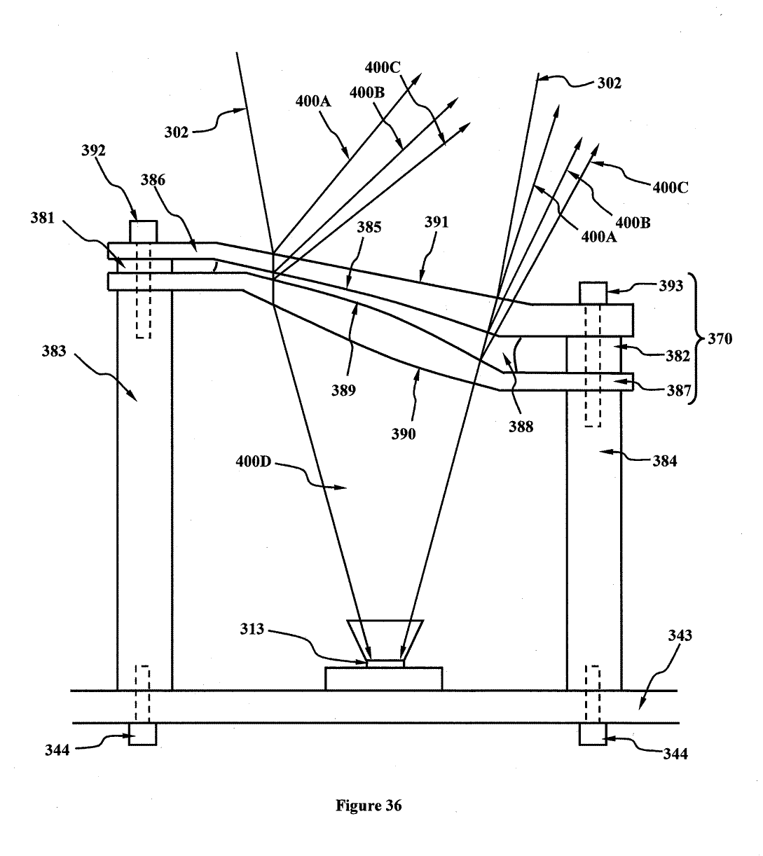

FIG. 36 is a cross-sectional view of a four-band spectral splitter reflector assembly 370. It features two substrates, an upper substrate 386 having a reflector 391 defining a planar upper surface that is treated to reflect a first band of wavelengths 400A, and a reflector 385 defining a non-planar lower surface, the non-planar lower surface being treated to reflect a second band of wavelengths 400B. Below the upper substrate 386 is a lower substrate 387 having a reflector 389 defining an upper non-planar surface, the upper non-planar surface being treated to reflect a third band of wavelengths 400C and a surface 390 through which all remaining non reflected wavelengths 400D are transmitted. Surface 390 is curved in accordance with previous descriptions of the lowermost non-reflecting surface such that it refracts or otherwise manipulates the light passing through it in such a way that it provides good uniformity when light 400D is incident on the active area of the lower PV-cell 313. Alternately, the surface 390 of the lower substrate 387 can be planar to save tooling costs associated with fabricating the lower substrate 387. Furthermore, reflector 391 of the upper substrate 386 can be curved in such a way as to improve the uniformity of the irradiance of the light incident on the active area of its associated PV-cell.

Shown between the two substrates 386 and 387 in FIG. 36 is a layer of adhesive 388 that serves to attach the two substrates 386 and 387 together as well as provide a good index match and eliminate the layer of air between the substrates 386 and 387 as described in previous paragraphs. This adhesive 388 can be a silicone, UV-curable glue, or solvent-curable glue. Note that the adhesive layer 388 must be substantially transparent and non-scattering to the two bands of wavelengths 400C and 400D that pass through it.

In addition to the adhesive layer 388 binding the two substrates 386 and 387 together, also shown in FIG. 28 are spacers 381 and 382 that, together with the placement of the mounting holes in the wings of the substrates 386 and 387, space the substrates 386 and 387 the correct distance apart and orient them with the correct alignment with respect to one another. The reflector assembly 370 is then attached to standoffs 383 and 384 with bolts 392 and 394, although other mounting methods and techniques can be used. For example, the snap clips as described in connection with 34A through 34E can be used to hold the two substrates together, and the spacers 381 and 382 can be dispensed with. Alternately, the spacers 381 and/or 382 can be integrally molded onto upper substrate 386 and/or lower substrate 387 to reduce manufacturing complexity.

Operation of the reflector assembly 370 shown in FIG. 36 is similar to the operation of reflector assemblies described in earlier embodiments. Converging light 302 that is made concentrated from a fresnel lens, diffractive optical element or the like (not shown in FIG. 36) is directed onto the reflector 391 of the upper substrate 386 of the reflector assembly 370. This upper surface defining a reflector is treated to reflect a first band of wavelengths 400A which are then reflected and directed to a first PV-cell (not shown) that is particularly responsive to the wavelengths of 400A and converts this optical energy to electricity with high efficiency. Wavelengths 400B, 400C, and 400D that are not reflected at the reflector 391 are transmitted into the upper substrate 386. Note that the material that the upper substrate is made from must be substantially transparent and non-scattering to these wavelengths. These wavelengths of light are then incident on the reflector 385 of the upper substrate 386. Reflector 385 defining a lower surface has been treated with a reflective material that reflects wavelength band 400B and transmits remaining wavelengths 400C and 400D. After reflection from reflector 385, the light energy of wavelength band 400B passes back through the upper substrate 386 and reflector 391 once again, and is directed to a second PV-cell (not shown in FIG. 36) that is particularly responsive to the wavelengths of 400B and converts this optical energy to electricity with high efficiency. If this second PV-cell is of large area (and operates best at moderately low concentrations such as 100×), then reflector 385 should be curved with a prescription that provides good uniformity of light across the active area of the second PV-cell. Wavelengths 400C and 400D that are not reflected at the reflector 385 are transmitted into the adhesive layer 388. These wavelengths of light are then incident on the reflector 389 of the lower substrate 387. Reflector 389 has been treated with a reflective material that reflects wavelength band 400C and transmits the remaining wavelength band 400D. After reflection from reflector 389, light containing wavelength band 400C passes once again through the adhesive layer 388, the reflector 385 of the upper substrate 386, the upper substrate 386 itself, and the reflector 391 of the upper substrate 386 after which it becomes incident on the active area of a third PV-cell that is particularly responsive to the wavelength band 400C and converts this light energy to electrical energy with high efficiency. Note that reflector 389 of the lower substrate 387 may be curved or planar in shape, depending on the whether or not the extra cost of a curved surface is justified in order to improve the uniformity of the light incident on the active area of the third PV-cell. Lastly, wavelength band 400D is transmitted through the reflector installed on reflector 389 of the lower substrate 387, whereupon it is also transmitted through the lower substrate 387 itself, and is subsequently transmitted through the surface 390 of the lower substrate 387 whereupon it is directed onto a fourth PV-cell 313 that is particularly responsive to the wavelength band 400D and converts this optical energy to electrical energy with high efficiency. Note that surface 390 of the lower substrate 387 may be curved or planar in shape, depending on whether or not the extra cost of a curved surface is justified in order to improve the uniformity of the light incident on the active area of the fourth PV-cell 313.

In one embodiment, each variation of a substrate set forth herein, e.g., substrate 43A, substrate 43B, substrate 43C, substrate 43D, substrate 43E, substrate 143B, substrate 243, substrate 321, substrate 324, substrate 330, substrate 365, substrate 386, substrate 387, substrate 443A, substrate 443B, substrate 443C, substrate 443D, can be of single piece construction. A substrate of single piece construction can have a reflective surface coated or otherwise formed therein. Suitable materials for a substrate as set forth herein include e.g., glass or a polymer material, e.g., acrylic or polycarbonate.

Shown in FIG. 37 is a three-band spectral splitter in which the two spectral-splitting reflectors are installed onto a single substrate 365, as was previously described in connection with FIG. 35. While lower reflector 335 is still curved as described previously to provide the advantage of improved illumination uniformity on the active area of the large area PV-cell 309, the upper reflector 327 is curved as well. Operation of the spectral-splitting converter shown in FIG. 37 is substantially the same as the operation of the spectral-splitting converter shown in FIG. 35, except having a curved upper reflector 327 allows for i) the addition of optical power to the reflector 327 which facilitates the placement of the corresponding PV-cell either closer or further away from the spectral-splitter as needed, for example, to facilitate PV-cell mounting, or ii) to offer an additional degree of optical design freedom that can be used, for example, to improve the uniformity of the light incident on the corresponding PV-cell. In either case, the converging bundle of light 305A reflected from reflective surface 327 has an angular intensity distribution that is different than the angular intensity distribution of converging bundle of light 305 reflected from planar reflector 320 of FIG. 35.

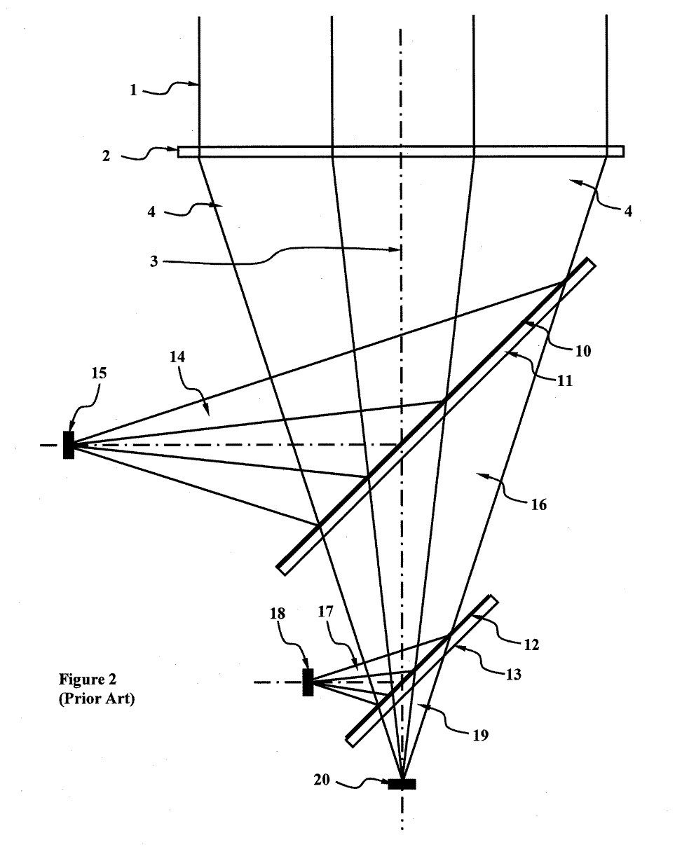

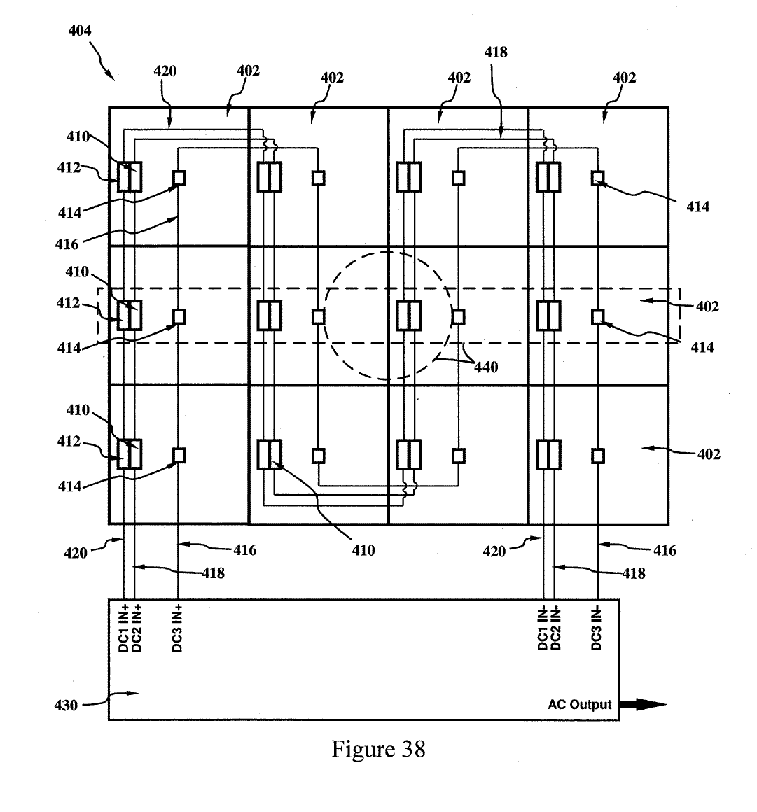

FIG. 38 presents a 3×4 array 404 of three-band converters 402, wherein converter 402 can be constructed in accordance with any converter set forth herein, e.g., the converter described with reference to FIG. 2, the converter described with reference to FIG. 3, the converter described with reference to FIG. 4, the converter described with reference to FIG. 5, the converter described with reference to FIG. 6, the converter described with reference to FIG. 7, the converter described with reference to FIG. 8, the converter described with reference to FIG. 9, the converter described with reference to FIG. 10, the converter described with reference to FIG. 11, the converter described with reference to FIG. 12, the converter described with reference to FIG. 13, the converter described with reference to FIG. 14, the converter described with reference to FIG. 15, the converter described with reference to FIG. 16, the converter described with reference to FIG. 17, the converter described with reference to FIG. 27, the converter described with reference to FIG. 28, the converter described with reference to FIGS. 34A-34B, the converter described with reference to FIGS. 34C-34D, the converter described with reference to FIG. 34E, the converter described with reference to FIG. 35, the converter described with reference to FIG. 36, the converter described with reference to FIG. 37, repeated (having the same or substantially the same configuration) and can be disposed in an array of light converter each being like configured. PV-cells of converter 402 can be electrically connected with one another and with an inverter 430 that can convert the DC energy provided by array 404 into AC electrical power.

Referring to one illustrative embodiment converter 402 can have three PV-cells 410, 412, and 414, wherein each three-band converter 402 of the array 404 possesses one PV-cell of type 410, as well as one PV-cell of type 412, as well as one PV-cell of type 414. The PV-cells, e.g., cells 410, 412, 414 can be electrically connected with one another and with an inverter 430 that can convert the DC electrical energy produced by array 404 into AC electrical power that can be utilized by most common household, commercial, and industrial electrical appliances. Note that inverter 430 can be a single inverter with multiple inputs as shown in FIG. 38, or multiple inverters with single inputs, or a combination of these configurations.

Since individual PV-cells produce high-amperage low-voltage electrical power, it is desirable to connect the PV-cells in series so that the total amperage is not increased (and therefore not necessitating a corresponding expensive increase in wire diameter to handle the extra current), but so that the total voltage is increased. While connecting different types of PV-cells together in series does indeed offer increased voltage, the current of the series string is limited to that PV-cell in the string which is producing the least amount of current. Since the current produced by a PV-cell is a strong function of the bandgap of the material comprising the cell, the highest system efficiency can be obtained by connecting only like PV-cells together in series. As shown in FIG. 38, three series strings of PV-cells are connected together. For example, there are twelve bandgap 1 PV-cells 412 connected together in series by connecting wires 420, which are in turn connected to the DC1 IN+ and DC1 IN− terminals of an inverter 430. Also there are twelve bandgap 2 PV-cells 410 connected together in series by connecting wires 418, which are in turn connected to the DC2 IN+ and DC2 IN− terminals of an inverter 430. Lastly, twelve bandgap 3 PV-cells 414 are connected together in series with connecting wires 416, which are in turn connected to the DC3 IN+ and DC3 IN− terminals of an inverter 430. In this example, bandgap 1 PV-cells 412 might be InGaP PV-cells, bandgap 2 PV-cells 410 might be silicon PV-cells, and bandgap 3 PV-cells 412 might be Germanium PV-cells, although other materials and bandgaps and numbers of PV-cells could be used. It is important that the PV-cells within a series string have similar current-producing characteristics or otherwise produce the same amount of current within the electro-optical conversion system. While converters 402 are shown in the specific embodiment of FIG. 38 as including three spectral bands, it is understood that converters 402 can be scaled to any number of spectral banks. Lastly, while the array 404 of FIG. 38 is a 3×4 array, other arrays are possible, e.g., 2×2, 3×3, 4×4, 5×3, 8×8, 120×150, N×M where N and M are arbitrary integers.

In one embodiment, the array 404 of converters 402 can be aimed at the source of input light so that the distinct bands of concentrated light are respectively directed onto the PV-cells such that the center of the several focal regions is substantially co-located with the center of the several PV-cells. This aiming function can be accomplished with a device that senses or otherwise determines the locations of the sun and angularly orients the array 404 of converters 402 for optimal focal spot location which coincidentally is the angular orientation of the array 404 that produces the maximum conversion efficiency. The pointing device or tracker 440 should achieve an angular pointing error of less than 2°, although pointing errors of less than 0.25° are preferred. Since the tracker 440 can be a relatively expensive device, the number of converters 402 in an array 404 mounted onto a tracker can be increased for reduction of an assembly including an array 404 and a tracker 440, provided the tracker has the mechanical strength to carry and angularly orient the large number of converters 402 in the presence of heavy wind and other loads. The number of converters 402 in an array 404 carried by a tracker 440 can be from as few as four to as many as 5,000 or more converters.

While the invention described heretofore has been directed at solar photovoltaic conversion, the physical embodiment of a condensing lens 30, 70, or 301 followed by a spectrum-separating reflector assembly 40, 304, 339, or 370 which directs the spectrally separated light to a series of receivers can also be utilized in telecommunication systems employing wavelength division multiplexing wherein several wavelengths or wavelength bands are transmitted over a single optical path and each such wavelength or wavelength band carries digital data. In such a configuration the individual wavelengths or wavelength bands must first be combined onto a single optical path by way of an optical multiplexing process at the transmitting end, and then the individual wavelengths or wavelength bands must then be separated or de-multiplexed at the receiving side. Since each wavelength or wavelength group carries it own digital data, the amount of data carried over a single optical path or channel can be increased manifold by using several communication wavelengths or wavelength bands. The present invention allows a simple way of de-multiplexing the several wavelengths or wavelength bands by replacing the sunlight illumination with the multiwavelength or multiband (polychromatic) light of the communication channel, and adjusting the spectral reflectance characteristics of the individual reflectors within the reflector assembly so they each reflect only one of the communication wavelengths or wavelength bands, and then providing a photodiode at each of the focal points of the several focused wavelengths or wavelength bands.

Alternately, the assembly can be made to operate as a multiplexer by having the present invention operate in reverse. For example if the receivers (or PV-cells) are replaced with emitters, each emitter emitting a distinct optical wavelength and also modulated with digital data, the emissions would all be directed to the reflector assembly which would redirect each of the diverging wavelength emissions to the fresnel lens. The fresnel lens would then substantially collimate the several-wavelength optical emissions, and direct the collimated output light into the optical communication path. Alternately the fresnel lens could cause the several-wavelength optical emissions to be brought to a focus, and the input end of an optical fiber placed at this focus so the multi-wavelength modulated light is input to the optical fiber for transmission to a remote location.

Having thus described the basic concept of the invention, it will be rather apparent to those skilled in the art that the foregoing detailed disclosure is intended to be presented by way of example only, and is not limiting. Various alterations, improvements, and modifications will occur and are intended to those skilled in the art, though not expressly stated herein. These alterations, improvements, and modifications are intended to be suggested hereby, and are within the spirit and scope of the invention. Additionally, the recited order of processing elements or sequences, or the use of numbers, letters, or other designations, such as arrows in the diagrams therefore is not intended to limit the claimed processes to any order or direction of travel of signals or other data and/or information except as may be specified in the claims. Accordingly, the invention is limited only by claims that can be supported by the specification herein and equivalents thereto.

A small sample of systems methods and apparatus that are described herein is as follows:

There is described (A1) an apparatus for converting solar energy, the apparatus comprising an optical element for converging solar radiation; and a reflector assembly receiving light transmitted by the optical element and including a first substrate having a first reflector and a second substrate spaced apart from the first substrate and having a second reflector, the first reflector being adapted to reflect a first spectral band of light transmitted by the optical element, the first reflector being adapted to transmit one or more spectral band of light outside of the first spectral band of light, the second reflector being adapted to reflect a second spectral band of light transmitted by the optical element, the second reflector being adapted to transmit one or more spectral band of light outside of the second spectral band, wherein the reflector assembly is configured so that a reflector of the first and second reflector transmits light reflected from the remaining of the first and second reflector, wherein the reflector assembly further includes adhesive material disposed between the first substrate and the second substrate, the adhesive material bonding the first substrate and the second substrate; wherein the apparatus for converting solar energy further comprises a first photovoltaic cell and a second photovoltaic cell, wherein the first photovoltaic cell is disposed to receive light reflected from the first reflector, wherein the second photovoltaic cell is disposed to receive light reflected from the second reflector, wherein the first photovoltaic cell is particularly responsive to the first spectral band of light, and wherein the second photovoltaic cell is particularly responsive to the second spectral band of light. There is also described (A2) the apparatus of A1, wherein the apparatus for converting solar energy is configured so that the first reflector is disposed more proximate the optical element than the second reflector. There is also described (A3) the apparatus of A1, wherein the apparatus is configured so that an index of refraction of the adhesive material is matched to an index of refraction of the first substrate, and wherein the apparatus is further configured so that the index of refraction of the adhesive material is matched to an index of refraction of the second substrate. There is also described (A4) the apparatus of A1, wherein the adhesive material has an index of refraction matched with an index of refraction of the first substrate. There is also described (A5) the apparatus of A1, wherein the adhesive material has an index of refraction matched with an index of refraction of the second substrate. There is also described (A6) the apparatus of A1, wherein the first substrate and the second substrate comprise material selected from the group consisting of glass and a polymer. There is also described (A7) the apparatus of A1, wherein the first substrate and the second substrate comprise material selected from the group consisting of glass and a polymer, and wherein the adhesive material comprises silicone. There is also described (A8) the apparatus of A1, wherein the adhesive material comprises silicone. There is also described (A9) the apparatus of A1, wherein the first reflector and the second reflector are non-parallel relative to one another. There is also described (A10) the apparatus of A1, wherein the adhesive material is wedge shaped. There is also described (A11) the apparatus of A1, wherein the adhesive material is a reactive adhesive. There is also described (A12) the apparatus of A1, wherein the adhesive material is non-reactive. There is also described (A13) the apparatus of A1, wherein the optical element is a fresnel lens. There is also described (A14) the apparatus of A1, wherein the first and second photovoltaic cells are mounted on a mounting block having a cooling channel for cooling of the first and second photovoltaic cells.

There is also described (B1) an apparatus for converting solar energy, the apparatus comprising an optical element for converging solar radiation; and a reflector assembly receiving light transmitted by the optical element and including a first substrate having a first reflector and a second substrate spaced apart from the first substrate and having a second reflector, the first reflector being adapted to reflect a first spectral band of light transmitted by the optical element, the first reflector being adapted to transmit one or more spectral band of light outside of the first spectral band of light, the second reflector being adapted to reflect a second spectral band of light transmitted by the optical element, the second reflector being adapted to transmit one or more spectral band of light outside of the second spectral band, wherein the reflector assembly is configured so that a reflector of the first and second reflector transmits light reflected from the remaining of the first and second reflector, wherein the reflector assembly further includes a layer of material disposed between the first substrate and the second substrate, the layer of material being in contact with the first substrate and the second substrate, wherein the layer of material has an index of refraction matched to an index of refraction of the first substrate; and wherein the apparatus for converting solar energy further comprises a first photovoltaic cell and a second photovoltaic cell, wherein the first photovoltaic cell is disposed to receive light reflected from the first reflector, wherein the second photovoltaic cell is disposed to receive light reflected from the second reflector, wherein the first photovoltaic cell is particularly responsive to the first spectral band of light, and wherein the second photovoltaic cell is particularly responsive to the second spectral band of light. There is also described (B2) the apparatus of B1, wherein the apparatus for converting solar energy is configured so that the first reflector is disposed more proximate the optical element than the second reflector. There is also described (B3) the apparatus of B1, wherein the index of refraction of the layer of material is further matched to the index of refraction of the second substrate. There is also described (B4) the apparatus of B1, wherein the first substrate and the second substrate comprise material selected from the group consisting of glass and a polymer. There is also described (B5) the apparatus of B1, wherein the adhesive material comprises silicone. There is also described (B6) the apparatus of B1, wherein the first substrate and the second substrate comprise material selected from the group consisting of glass and a polymer, and wherein the layer material comprises silicone. There is also described (B7) the apparatus of B1, wherein the layer of material is wedge shaped. There is also described (B8) the apparatus of B1, wherein the layer of material is capable of curing. There is also described (B9) the apparatus of B1, wherein for providing the apparatus, the layer of material is disposed between the first and second substrate in an uncured state and is subsequently cured. There is also described (B10) the apparatus of B1, wherein the apparatus is adapted so that for contact with the first and second substrate, the layer of material bonds the first and second substrate. There is also described (B11) the apparatus of B1, wherein the layer of material provided by a material that is capable of hardening responsively to one of applied radiation, heat, and pressure. There is also described (B12) the apparatus of B1, wherein the layer of material is adapted to conform to a shape of the first and second substrate. There is also described (B13) the apparatus of B1, wherein the layer of material is provided by an adhesive. There is also described (B14) the apparatus of B1, wherein the layer of material is in optical contact with the first substrate and second substrate. There is also described (B15) the apparatus of B1, wherein for providing the apparatus, the layer of material is disposed in a first state and subject to energy application so that the layer of material hardens to conform to a shape of the first and second substrate. There is also described (B16) the apparatus of B1, wherein the optical element is a fresnel lens.

There is also described (C1) an apparatus for converting solar energy, the apparatus comprising an optical element for converging solar radiation; and a reflector assembly receiving light transmitted by the optical element and including a first substrate having a first reflector and a second substrate spaced apart from the first substrate and having a second reflector, the first reflector being adapted to reflect a first spectral band of light transmitted by the optical element, the first reflector being adapted to transmit one or more spectral band of light outside of the first spectral band of light, the second reflector being adapted to reflect a second spectral band of light transmitted by the optical element, the second reflector being adapted to transmit one or more spectral band of light outside of the second spectral band, wherein the reflector assembly is configured so that a reflector of the first and second reflector transmits light reflected from the remaining of the first and second reflector, wherein the reflector assembly further includes a layer of material disposed between the first substrate and the second substrate, the layer of material being in contact with the first substrate and the second substrate; wherein the apparatus for converting solar energy further comprises a first photovoltaic cell and a second photovoltaic cell, wherein the first photovoltaic cell is disposed to receive light reflected from the first reflector, wherein the second photovoltaic cell is disposed to receive light reflected from the second reflector, wherein the first photovoltaic cell is particularly responsive to the first spectral band of light, and wherein the second photovoltaic cell is particularly responsive to the second spectral band of light. There is also described (C2) the apparatus of C1, wherein the apparatus for converting solar energy is configured so that the first reflector is disposed more proximate the optical element than the second reflector.

There is also described (D1) an apparatus comprising an array of converters, wherein first, second, and third converters of the array comprise an optical element for converging solar radiation, a first substrate including a first reflector and a second substrate including a second reflector, the first reflector being adapted to reflect a first spectral band of light transmitted by the optical element, the first reflector being adapted to transmit one or more other spectral band of light outside of the first spectral band of light, the second reflector adapted to reflect a second spectral band of light transmitted by the optical element, the second reflector of the first, second, and third converter being adapted to transmit one or more other spectral band of light outside of the second spectral band of light, each of the first, second, and third converter further having a first photovoltaic cell and a second photovoltaic cell, the first photovoltaic cell disposed to receive light reflected from the first reflector and being particularly responsive to the first spectral band of light, the second photovoltaic cell disposed to receive light reflected from the second reflector and being particularly responsive to the second spectral band of light, wherein the first, second, and third converter each includes a layer of material disposed between its respective first substrate and second substrate, the layer of material of the first, second, and third converter transmitting light in the second spectral band and having an index of refraction matched to an index of refraction of its respective first substrate. There is also described (D2) the apparatus of D1, wherein the apparatus is configured so that the first reflector of the first, second, and third converters is arranged more proximate its respective optical element than it respective second reflector. There is also described (D3) the apparatus of D1, wherein the index of refraction of the layer of material of the first, second, and third converter is further matched to an index of refraction of its respective second substrate.

There is also described (E1) an apparatus for converting solar energy, the apparatus comprising an optical element for converging solar radiation; a reflector assembly receiving light transmitted by the optical element and including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, said second reflector being adapted to transmit one or more other spectral band of light outside of the second spectral band of light, wherein the apparatus for converting solar energy is configured so that a reflector of the first and second reflector transmits light reflected from the remaining of the first and second reflector; wherein the apparatus for converting solar energy further includes a first photovoltaic cell and a second photovoltaic cell, the first photovoltaic cell being disposed to receive light reflected from the first reflector and being particularly responsive to the first spectral band of light, the first photovoltaic cell having a first active area, the second photovoltaic cell being disposed to receive light reflected from the second reflector and being particularly responsive to the second spectral band of light, the second photovoltaic cell having a second active area, the second active area having a surface area larger than a surface area of the first active area, wherein the second reflector is non-planar and includes a prescription adapting the apparatus so that light reflected by the second reflector is incident on the second active area in a distribution pattern that is more uniform than would be incident on the second active area in the case the second reflector were planar. There is also described (E2) the apparatus of E1, wherein the apparatus for converting solar energy is configured so that the first reflector is disposed more proximate the optical element than the second reflector. There is also described (E3) the apparatus of E1, wherein the second reflector is microstructured. There is also described (E4) the apparatus of E1, wherein the second reflector is curved in a single axis. There is also described (E5) the apparatus of E1, wherein the second reflector is curved in two axes. There is also described (E6) the apparatus of E1, wherein the prescription defining the second reflector is mathematically described by a polynomial. There is also described (E7) the apparatus of E1, wherein the first reflector is planar. There is also described (E8) the apparatus of E1, wherein the optical element is a fresnel lens. There is also described (E9) the apparatus of E1, wherein the first and second photovoltaic cells are mounted on a unitary mounting block. There is also described (E10) the apparatus of E1, wherein the second active surface area is defined by silicon, and wherein the first active surface area is defined by a material other than silicon. There is also described (E11) the apparatus of E1, wherein the surface area of the second active area is at least two times greater than the surface area of the first active area. There is also described (E12) the apparatus of E1, wherein the surface area of the second active area is at least four times greater than the surface area of the first active area. There is also described (E13) the apparatus of E1, wherein the apparatus includes secondary optics associated with the first photovoltaic cell adapted for increasing a uniformity of light received by the first photovoltaic cell.

There is also described (F1) an apparatus for converting solar energy, the apparatus comprising an optical element for converging solar radiation; a reflector assembly receiving light transmitted by the optical element and including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, the second reflector being adapted to transmit one or more other spectral band of light outside of the second spectral band of light, wherein the apparatus for converting solar energy is configured so that a reflector of the first and second reflector transmits light reflected from the remaining of the first and second reflector; wherein the apparatus for converting solar energy further includes a first photovoltaic cell and a second photovoltaic cell, the first photovoltaic cell being disposed to receive light reflected from the first reflector and being particularly responsive to the first spectral band of light, the first photovoltaic cell having a first active area, the second photovoltaic cell disposed to receive light reflected from the second reflector and being particularly responsive to the second spectral band of light, the second photovoltaic cell having a second active area, the second active area having a surface area that is at least 1.5 times the surface area of the first active area, wherein first active area is defined by a first type of material and wherein the second active area is defined by a second type of material. There is also described (F2) the apparatus of F1, wherein the apparatus for converting solar energy is configured so that the first reflector is disposed more proximate the optical element than the second reflector. There is also described (F3) the apparatus of F1, wherein the surface area of the second active area is at least two times the surface area of the second active area. There is also described (F4) the apparatus of F1, wherein the surface area of the second active area is at least three times the surface area of the second active area. There is also described (F5) the apparatus of F1, wherein the surface area of the second active area is at least four times the surface area of the second active area. There is also described (F6) the apparatus of F1, wherein the second reflector is non-planar and includes a prescription adapting the apparatus so that light reflected by the second reflector is incident on the second active surface area in a distribution pattern that is more uniform than would be incident on the second active surface area in the case the second reflector were planar. There is also described (F7) the apparatus of F5, wherein the second reflector is microstructured. There is also described (F8) the apparatus of F1, wherein the second reflector is curved in a single axis. There is also described (F9) the apparatus of F1, wherein the second reflector is curved in two axes. There is also described (F10) the apparatus of F1, wherein the prescription defining the second reflector is mathematically described by a polynomial. There is also described (F11) the apparatus of F1, wherein the first reflector is planar. There is also described (F12) the apparatus of F1, wherein the optical element is a fresnel lens. There is also described (F13) the apparatus of F1, wherein the first and second photovoltaic cells are mounted on a common planar surface of a mounting apparatus. There is also described (F14) the apparatus of F1, wherein the second active area is defined by silicon, and wherein the first active area is defined by a material other than silicon. There is also described (F15) the apparatus of F1, wherein the surface area of the second active area is more than two times greater than the surface area of the first active area. There is also described (F16) the apparatus of F1, wherein the surface area of the second active area is more than four times greater than the surface area of the first active area. There is also described (F17) the apparatus of F1, wherein the apparatus includes secondary optics for increasing a uniformity of light. There is also described (F18) the apparatus of F1, wherein the first and second photovoltaic cells are mounted on a unitary mounting block.

There is also described (G1) an apparatus comprising an array of converters, wherein first, second, and third converters of the array comprise an optical element for converging solar radiation, a first reflector and a second reflector, the first reflector of the first, second, and third converter adapted to reflect a first spectral band of light transmitted by its respective optical element, the first reflector being adapted to transmit one or more other spectral band of light outside of the first spectral band of light, the second reflector of the first, second, and third converter being adapted to reflect a second spectral band of light transmitted by its respective optical element, the second reflector of the first, second, and third converter being adapted to transmit one or more other spectral band of light outside of the second spectral band of light, wherein the first, second, and third converter further include a first photovoltaic cell and a second photovoltaic cell, the first photovoltaic cell of the first, second, and third converter being disposed to receive light reflected from its respective first reflector and being particularly responsive to the first spectral band of light, the second photovoltaic cell of the first, second, and third converter being disposed to receive light reflected from its respective second reflector and being particularly responsive to the second spectral band of light, the second photovoltaic cell of the first, second, and third converter having an active area surface area that is at least 1.5 times an active area surface area of its respective first photovoltaic cell, wherein the active area of the first photovoltaic cell of the first, second, and third converters is defined by a first type of material and wherein the active area of the second photovoltaic cell of the first, second, and third converter is defined by a second type of material. There is also described (G2) the apparatus of G1, wherein the first photovoltaic cell and the second photovoltaic cell of the first, second, and third converter are each connected to an inverter that converts input electrical power from the first, second, and third converter for output of AC electrical power. There is also described (G3) the apparatus of G1, wherein the apparatus is configured so that the first reflector of the first, second, and third converters is arranged more proximate its respective optical element than its respective second reflector. There is also described (G4) the apparatus of G1, wherein the apparatus is configured so that one or more of the first reflector and second reflector of said each first, second, and third converter is non-planar. There is also described (G5) the apparatus of G1, wherein the first photovoltaic cell of the first, second and third converters has an active area surface area of about 8 mm×8 mm, and wherein the second photovoltaic cell of the first, second and third converter has an active area surface area of about 20 mm×20 mm. There is also described (G6) the apparatus of G1, wherein first photovoltaic cell of the first, second, and third converters are connected in series, and wherein the second photovoltaic cell of the first, second, and third converters are connected in series.

There is also described (H1) an apparatus for converting solar energy, the apparatus comprising an optical element for converging solar radiation; a reflector assembly receiving light transmitted by the optical element including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, said second reflector being adapted to transmit one or more other spectral band of light outside of the second spectral band of light; wherein the apparatus further includes a first photovoltaic cell and a second photovoltaic cell, the first photovoltaic cell being disposed to receive light reflected from the first reflector and being particularly responsive to the first spectral band of light, the first photovoltaic cell having a first active surface area, the second photovoltaic cell being disposed to receive light reflected from the first reflector and being particularly responsive to the second spectral band of light, the second photovoltaic cell having a second active surface area, the second active surface area being larger than the first active surface area, and wherein the first photovoltaic cell and the second photovoltaic cell are disposed substantially in a common plane.

There is also described (I1) an apparatus for converting solar energy, the apparatus comprising an optical element for converging solar radiation; a reflector assembly receiving light transmitted by the optical element including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, said second reflector being adapted to transmit one or more other spectral band of light outside of the second spectral band of light, wherein the reflector assembly includes a substrate that has formed thereon each of the first reflector and the second reflector; wherein the apparatus further includes a first photovoltaic cell and a second photovoltaic cell, the first photovoltaic cell being disposed to receive light reflected from the first reflector and being particularly responsive to the first spectral band of light, the first photovoltaic cell having a first active surface area, the second photovoltaic cell being disposed to receive light reflected from the first reflector and being particularly responsive to the second spectral band of light, the second photovoltaic cell having a second active surface area, the second active surface area being larger than the first active surface area.

There is also described (J1) an apparatus for obtaining energy from a polychromatic radiant energy source, the apparatus comprising (a) a fresnel lens concentrator, (b) a spectral separator comprising (i) a first surface treated to reflect a first spectral band of light received from the fresnel lens concentrator toward a first focal region; and to transmit one or more other spectral bands; (ii) a plurality of additional surfaces spaced apart from the first surface and from each other, wherein the plurality of surfaces are treated to reflect different spectral bands of light back through the first surface and toward focal regions that are spaced apart from the first focal region and from each other; (c) a first light receiver, (d) a plurality of additional light receivers, wherein the first light receiver is located at the first focal region for receiving the first spectral band and the plurality of additional light receivers are located at a focal region for receiving the spectral band of light that each is most responsive to. There is also described (J2) the apparatus according to J1 wherein the first surface is planar. There is also described (J3) the apparatus according to J1 wherein the first surface has optical power. There is also described (J4) the apparatus according to J1 wherein the first surface is microstructured. There is also described (J5) the apparatus according to J1 wherein one or more of the plurality of surfaces are planar. There is also described (J6) the apparatus according to J1 wherein one or more of the plurality of surfaces has optical power. There is also described (J7) the apparatus according to J1 wherein one or more of the plurality of surfaces is microstructured. There is also described (J8) the apparatus according to J1 wherein the plurality of surfaces are rotated with respect to one another. There is also described (J9) the apparatus according to J8 wherein the axis of rotation are parallel. There is also described (J10) the apparatus according to J8 wherein there are two parallel axis of rotation resulting in a compound angle being formed between at least two of the plurality of surfaces. There is also described (J11) the apparatus according to J1 wherein the number of reflective surfaces comprising the plurality surfaces is between two and ten. There is also described (J12) the apparatus according to J1 wherein a reflective surface treatment is a dielectric film stack. There is also described (J13) the apparatus according to J1 wherein a reflective surface treatment is a metallic film. There is also described (J14) the apparatus according to J1 wherein one or more of the surfaces are molded onto a substrate. There is also described (J15) the apparatus according to J7 wherein one or more of the microstructured surfaces are molded onto a substrate. There is also described (J16) the apparatus according to J15 wherein the microstructure material is silicone. There is also described (J17) the apparatus according to J15 wherein the substrate material is a glass material. There is also described (J18) the apparatus according to J16 wherein a supporting rigid layer is installed between the silicone microstructure and the reflective treatment. There is also described (J19) the apparatus according to J15 wherein the molding process is one of an injection molding process, a compression molding process, or an injection-compression molding process. There is also described (J20) the apparatus according to J15 wherein the molded material is one of acrylic or polycarbonate. There is also described (J21) the apparatus according to J1 wherein the spectral separator is located on the optical axis of the condensing fresnel lens. There is also described (J22) the apparatus according to J1 wherein the spectral separator is not located on the optical axis of the condensing fresnel lens. There is also described (J23) the apparatus according to J1 wherein the first and plurality of surfaces are not parallel with the condensing fresnel lens. There is also described (J24) the apparatus according to J1 wherein the first and plurality of receivers are all located within a plane. There is also described (J25) the apparatus according to J1 wherein the first and plurality of receivers are all provided with a planar rear surface for mounting. There is also described (J26) the apparatus according to J25 wherein the first and plurality of receivers are all mounted on a unitary mounting block. There is also described (J27) the apparatus according to J25 wherein the first and plurality of planar rear mounting surfaces of the receivers are all coplanar. There is also described (J28) the apparatus according to J1 wherein the wavelengths present in the spectral bands are selected in accordance with the spectral responsivities of the first and plurality of receivers. There is also described (J29) the apparatus according to J1 wherein the wavelengths present in the spectral bands are selected such that the power present in each spectral band are substantially equal. There is also described (J30 the apparatus according to J1 wherein the wavelengths present in the spectral bands are selected such that the power present in each spectral band is within 50% of the power present in each of the other spectral bands. There is also described (J31) the apparatus according to J1 wherein the polychromatic light source is the sun. There is also described (J32) the apparatus according to J31 wherein the spectrally separated sunlight is converted to electricity. There is also described (J33) the apparatus according to J32 wherein the first and plurality of receivers are photovoltaic converters. There is also described (J34) the apparatus according to J1 wherein the polychromatic light source is from a telecommunications transmitter. There is also described (J35 the apparatus according to J34 wherein one or more of the spectrally separated light bands carry data There is also described (J36) the apparatus according to J35 wherein the first and plurality of receivers are optical fibers.

While the present invention has been described with reference to a number of specific embodiments, it will be understood that the true spirit and scope of the invention should be determined only with respect to claims that can be supported by the present specification. Further, while in numerous cases herein wherein systems and apparatuses and methods are described as having a certain number of elements it will be understood that such systems, apparatuses and methods can be practiced with fewer than or more than the mentioned certain number of elements. Also, while a number of particular embodiments have been set forth, it will be understood that features and aspects that have been described with reference to each particular embodiment can be used with each remaining particularly set forth embodiment.

What is claimed is:

1. An apparatus for converting solar energy, the apparatus comprising:
an optical element for converging solar radiation;
a reflector assembly receiving light transmitted by the optical element and including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, said second reflector being adapted to transmit one or more other spectral band of light outside of the second spectral band of light, wherein the apparatus for converting solar energy is configured so that a reflector of the first and second reflector transmits light reflected from the remaining of the first and second reflector;
wherein the apparatus for converting solar energy further includes a first photovoltaic cell and a second photovoltaic cell, the first photovoltaic cell being disposed to receive light reflected from the first reflector and being particularly responsive to the first spectral band of light, the first photovoltaic cell having a first active area, the second photovoltaic cell being disposed to receive light reflected from the second reflector and being particularly responsive to the second spectral band of light, the second photovoltaic cell having a second active area, the second active area having a surface area larger than a surface area of the first active area, wherein the second reflector is non-planar and includes a prescription adapting the apparatus so that light reflected by the second reflector is incident on the second active area in a distribution pattern that is more uniform than would be incident on the second active area in the case the second reflector were planar.

2. The apparatus of claim 1, wherein the apparatus for converting solar energy is configured so that the first reflector is disposed more proximate the optical element than the second reflector.

3. The apparatus of claim 1, wherein the second reflector is microstructured.

4. The apparatus of claim 1, wherein the second reflector is curved in a single axis.

5. The apparatus of claim 1, wherein the second reflector is curved in two axes.

6. The apparatus of claim 1, wherein the first reflector is planar.

7. The apparatus of claim 1, wherein the optical element is a fresnel lens.

8. The apparatus of claim 1, wherein the first and second photovoltaic cells are mounted on a unitary mounting block.

9. The apparatus of claim 1, wherein the second active surface area is defined by silicon, and wherein the first active surface area is defined by a material other than silicon.

10. The apparatus of claim 1, wherein the surface area of the second active area is at least two times greater than the surface area of the first active area.

11. An apparatus for converting solar energy, the apparatus comprising:
an optical element for converging solar radiation;
a reflector assembly receiving light transmitted by the optical element and including a first reflector and a second reflector, the first reflector being adapted to reflect a first spectral band of light transmitted by the optical element, the first reflector being adapted to transmit one or more other spectral band of light outside of the first spectral band of light, the second reflector being adapted to reflect a second spectral band of light transmitted by the optical element, the second reflector being adapted to transmit one or more other spectral band of light outside of the second spectral band of light, wherein the apparatus for converting solar energy is configured so that a reflector of the first and second reflector transmits light reflected from the remaining of the first and second reflector;
wherein the apparatus for converting solar energy further includes a first photovoltaic cell and a second photovoltaic cell, the first photovoltaic cell being disposed to receive light reflected from the first reflector and being particularly responsive to the first spectral band of light, the first photovoltaic cell having a first active area, the second photovoltaic cell disposed to receive light reflected from the second reflector and being particularly responsive to the second spectral band of light, the second photovoltaic cell having a second active area, the second active area having a surface area that is at least 1.5 times the surface area of the first active area, wherein first active area is defined by a first type of material and wherein the second active area is defined by a second type of material.

12. The apparatus of claim 11, wherein the second reflector is non-planar and includes a prescription adapting the apparatus so that light reflected by the second reflector is incident on the second active surface area in a distribution pattern that is more uniform than would be incident on the second active surface area in the case the second reflector were planar.

13. The apparatus of claim 11, wherein the second reflector is curved in a single axis.

14. The apparatus of claim 11, wherein the second reflector is curved in two axes.

15. The apparatus of claim 11, wherein the optical element is a fresnel lens.

16. The apparatus of claim 11, wherein the second active area is defined by silicon, and wherein the first active area is defined by a material other than silicon.

17. The apparatus of claim 11, wherein the apparatus includes secondary optics for increasing a uniformity of light.

18. The apparatus of claim 11, wherein the first and second photovoltaic cells are mounted on a unitary mounting block.

19. An apparatus comprising:
an array of converters, wherein first, second, and third converters of the array comprise an optical element for converging solar radiation, a first reflector and a second reflector, the first reflector of the first, second, and third converter adapted to reflect a first spectral band of light transmitted by its respective optical element, the first reflector being adapted to transmit one or more other spectral band of light outside of the first spectral band of light, the second reflector of the first, second, and third converter being adapted to reflect a second spectral band of light transmitted by its respective optical element, the second reflector of the first, second, and third converter being adapted to transmit one or more other spectral band of light outside of the second spectral band of light, wherein the first, second, and third converter further include a first photovoltaic cell and a second photovoltaic cell, the first photovoltaic cell of the first, second, and third converter being disposed to receive light reflected from its respective first reflector and being particularly responsive to the first spectral band of light, the second photovoltaic cell of the first, second, and third converter being disposed to receive light reflected from its respective second reflector and being particularly responsive to the second spectral band of light, the second photovoltaic cell of the first, second, and third converter having an active area surface area that is at least 1.5 times an active area surface area of its respective first photovoltaic cell, wherein the active area of the first photovoltaic cell of the first, second, and third converters is defined by a first type of material and wherein the active area of the second photovoltaic cell of the first, second, and third converter is defined by a second type of material.

20. The apparatus of claim 19, wherein the first photovoltaic cell and the second photovoltaic cell of the first, second, and third converter are each connected to an inverter that converts input electrical power from the first, second, and third converter for output of AC electrical power.
